(19) United States
(12) Patent Application Publication
(10) Pub. No.: US 2025/0347998 A1
(43) Pub. Date: Nov. 13, 2025

(54) ALKOXY GROUP-CONTAINING COMPOSITION FOR FORMING RESIST UNDERLAYER FILM

(71) Applicant: NISSAN CHEMICAL CORPORATION, Tokyo (JP)

(72) Inventors: Hiroto OGATA, Toyama-shi (JP); Mamoru TAMURA, Toyama-shi (JP)

(73) Assignee: NISSAN CHEMICAL CORPORATION, Tokyo (JP)

(21) Appl. No.: 18/703,037

(22) PCT Filed: Nov. 9, 2022
(86) PCT No.: PCT/JP2022/041632

§ 371 Date: Jul. 14, 2025

(30) Foreign Application Priority Data
Nov. 10, 2021 (JP) 2021-183314

(51) Int. Cl. G03F 7/039; C09D 139/04; G03F 7/00; G03F 7/095; G03F 7/36; H01L 21/311

(52) U.S. Cl. CPC G03F 7/039; C09D 139/04; G03F 7/095; G03F 7/36; G03F 7/70033; H01L 21/31144

(57) ABSTRACT

A composition for forming a resist underlayer film for use in EB or EUV lithography, the composition containing a film-forming component and a solvent, wherein the film-forming component contains 20 mass % or more of a specific structure-containing component containing at least either of a first structure containing an aromatic ring and a second structure containing a nitrogen atom, the first structure contains a group represented by formula (1) below directly bonded to the aromatic ring, and the second structure contains a group represented by formula (1) below directly bonded to the nitrogen atom.

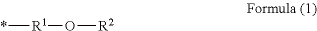

In formula (1), R¹ represents an alkylene group having 1 to 6 carbon atoms, R² represents a hydrogen atom, an alkyl group having 1 to 6 carbon atoms, or an alkoxyalkyl group having 2 to 10 carbon atoms in total, and * represents a bond.

### TECHNICAL FIELD

The present invention relates to a composition for forming a resist underlayer film for use in EB or EUV lithography, a resist underlayer film for use in EB or EUV lithography, a substrate for semiconductor processing, a method for producing a semiconductor element, a method for forming a pattern, and a method for improving LWR of a resist pattern.

### BACKGROUND ART

In a semiconductor device such as a semiconductor integrated circuit (LSI), formation of a fine pattern is required with the increase in the degree of integration, and a minimum pattern size in recent years has reached 100 nm or less.

Such formation of a fine pattern in a semiconductor device has been achieved by shortening the wavelength of a light source in an exposure apparatus and improving a resist material. At present, an immersion exposure method in which exposure is performed using argon fluoride (ArF) excimer laser light having a wavelength of 193 nm, which is deep ultraviolet light, as a light source through water is performed, and various ArF-compatible resist materials based on an acrylic resin have also been developed as resist materials.

Further, as a next-generation exposure technology, an EB exposure method using an electron beam (EB) or an EUV (extreme ultraviolet) exposure method using a soft X-ray having a wavelength of 13.5 nm as a light source has been studied, and further reduction in pattern size has been advanced such that the pattern size is 30 nm or less.

However, along with such reduction in pattern size, roughness of a sidewall of a resist pattern (line edge roughness: LER) and non-uniformity of a width of a resist pattern (line width roughness: LWR) increase, and there is an increasing concern that the device performance is adversely affected. Studies have been conducted to prevent these problems by optimizing an exposure apparatus, a resist material, and process conditions, but sufficient results have not been obtained. Note that LWR and LER are related, and LER is also improved by improving LWR.

As a method for solving the above-mentioned problems, there has been disclosed a method for improving the LWR and LER by treating a resist pattern using an aqueous solution containing a specific ionic surfactant in a rinsing step after development processing so as to prevent defects (defects such as generation of residues and pattern collapse) due to the development processing, and at the same time, to dissolve the roughness of the resist pattern (see Patent Literature 1).

### CITATION LIST

### Patent Literature

Patent Literature 1: JP 2007-213013 A

### SUMMARY OF INVENTION

### Technical Problem

An object of the present invention is to provide a composition for forming a resist underlayer film for use in EB or EUV lithography, a resist underlayer film for use in EB or EUV lithography, a substrate for semiconductor processing, a method for producing a semiconductor element, a method for forming a pattern, and a method for improving LWR of a resist pattern, with which LWR of a resist pattern in EB or EUV lithography can be improved.

### Solution to Problem

As a result of intensive studies to solve the above-mentioned problems, the present inventors found that the above-mentioned problems can be solved, and completed the present invention having the following gist.

That is, the present invention includes the following aspects.

[1] A composition for forming a resist underlayer film for use in EB or EUV lithography, the composition containing a film-forming component and a solvent, wherein
the film-forming component contains 20 mass % or more of a specific structure-containing component containing at least either of a first structure containing an aromatic ring and a second structure containing a nitrogen atom,
the first structure contains a group represented by formula (1) below directly bonded to the aromatic ring, and
the second structure contains a group represented by formula (1) below directly bonded to the nitrogen atom.

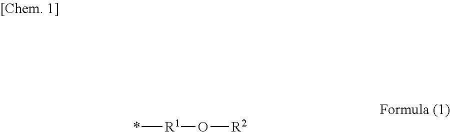

In formula (1), R¹ represents an alkylene group having 1 to 6 carbon atoms, R² represents a hydrogen atom, an alkyl group having 1 to 6 carbon atoms, or an alkoxyalkyl group having 2 to 10 carbon atoms in total, and * represents a bond.

[2] The composition for forming a resist underlayer film for use in EB or EUV lithography according to [1], wherein
the specific structure-containing component contains a polymer, and the polymer contains at least either of the first structure and the second structure.

[3] The composition for forming a resist underlayer film for use in EB or EUV lithography according to [2], wherein the polymer contains, as the first structure, at least any of a structure represented by formula (11) below, a structure represented by formula (12) below, and a structure represented by formula (13) below.

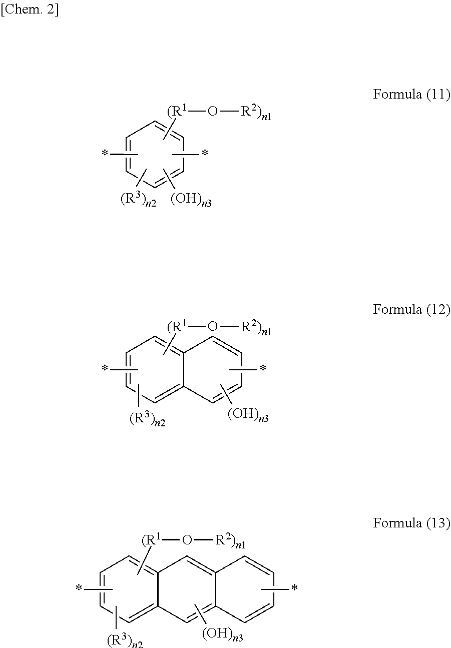

In formula (11) to formula (13), R¹'s each independently represent an alkylene group having 1 to 6 carbon atoms, R²'s each independently represent a hydrogen atom, an alkyl group having 1 to 6 carbon atoms, or an alkoxyalkyl group having 2 to 10 carbon atoms in total, R³'s each independently represent an alkyl group having 1 to 6 carbon atoms, and * represents a bond;
in formula (11), n1 represents an integer of 1 to 4, n2 represents an integer of 0 to 3, n3 represents an integer of 0 to 3, and n1, n2, and n3 satisfy 1≤(n1+n2+n3)≤4;
in formula (12), n1 represents an integer of 1 to 6, n2 represents an integer of 0 to 5, n3 represents an integer of 0 to 5, and n1, n2, and n3 satisfy 1≤(n1+n2+n3)≤6;
in formula (13), n1 represents an integer of 1 to 8, n2 represents an integer of 0 to 7, n3 represents an integer of 0 to 7, and n1, n2, and n3 satisfy 1≤(n1+n2+n3)≤8;
in formula (11) to formula (13), when there are two or more R¹'s, the two or more R¹'s may be identical or different, when there are two or more R²'s, the two or more R²'s may be identical or different, and when there are two or more R³'s, the two or more R³'s may be identical or different.

[4] The composition for forming a resist underlayer film for use in EB or EUV lithography according to [3], wherein the polymer includes, as a repeating unit containing the structure represented by formula (11), at least either of a repeating unit represented by formula (11-1) below and a repeating unit represented by formula (11-2) below.

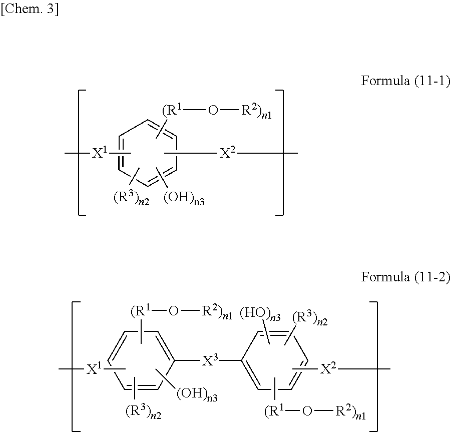

In formula (11-1) and formula (11-2), R¹'s each independently represent an alkylene group having 1 to 6 carbon atoms, R²'s each independently represent a hydrogen atom, an alkyl group having 1 to 6 carbon atoms, or an alkoxyalkyl group having 2 to 10 carbon atoms in total, R³'s each independently represent an alkyl group having 1 to 6 carbon atoms, n1's each independently represent an integer of 1 to 4, n2's each independently represent an integer of 0 to 3, and n3's each independently represent an integer of 0 to 3;
in formula (11-1), X¹ and X² each independently represent a single bond, an oxygen atom, or a methylene group;
in formula (11-2), X¹ and X² each independently represent a single bond, an oxygen atom, or a methylene group, and X³ represents a single bond or a divalent organic group having 1 to 15 carbon atoms;
in formula (11-1), n1, n2, and n3 satisfy 1≤(n1+n2+n3)≤4;
in formula (11-2), n1, n2, and n3 in a benzene ring on a left side satisfy 1≤(n1+n2+n3)≤4, and n1, n2, and n3 in a benzene ring on a right side satisfy 1≤(n1+n2+n3)≤4; and in formula (11-1) and formula (11-2), when there are two or more R¹'s, the two or more R¹'s may be identical or different, when there are two or more R²'s, the two or more R²'s may be identical or different, and when there are two or more R³'s, the two or more R³'s may be identical or different.

[5] The composition for forming a resist underlayer film for use in EB or EUV lithography according to any one of [2] to [4], wherein the polymer includes a repeating unit represented by formula (14) below.

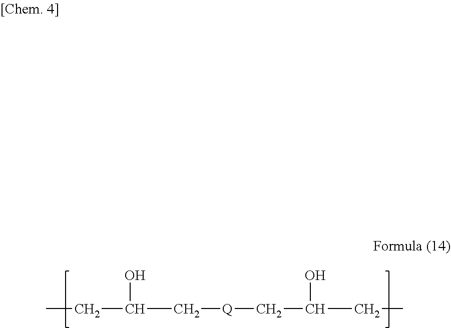

[6] The composition for forming a resist underlayer film for use in EB or EUV lithography according to [5], wherein in formula (14), Q represents a divalent group represented by formula (14-1) below or an arylene group having 6 to 40 carbon atoms.

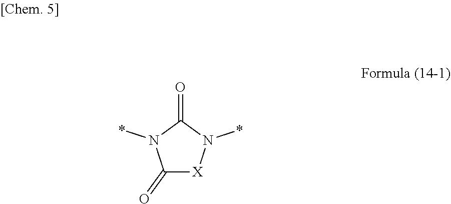

In formula (14-1), X represents a group represented by any of formulae (14-1a) to (14-1) below.

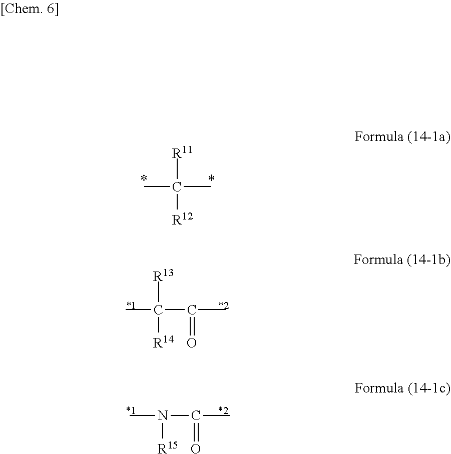

In formulae (14-1a) to (14-1c), R¹¹, R¹², R¹³, R¹⁴, and R¹⁵ each independently represent a hydrogen atom, an alkyl group having 1 to 6 carbon atoms, an alkenyl group having 3 to 6 carbon atoms, a benzyl group, or a phenyl group, and the benzyl group and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms, R¹¹ and R¹² may be bonded to each other to form a ring having 3 to 6 carbon atoms, R¹³ and R¹⁴ may be bonded to each other to form a ring having 3 to 6 carbon atoms, * represents a bond, *1 represents a bond bonded to a carbon atom, and *2 represents a bond bonded to a nitrogen atom.

[7] The composition for forming a resist underlayer film for use in EB or EUV lithography according to [1], wherein the specific structure-containing component contains a crosslinking agent, and the crosslinking agent contains at least any of a compound represented by formula (21) below, a compound represented by formula (22) below, and a compound represented by formula (23) below.

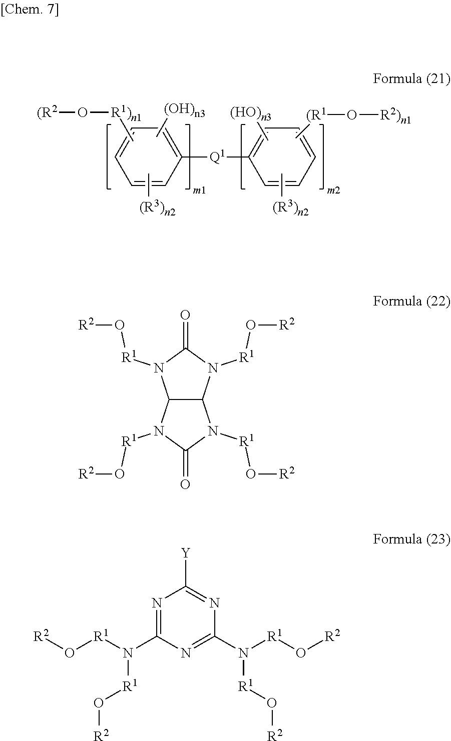

In formula (21) to formula (23), R¹'s each independently represent an alkylene group having 1 to 6 carbon atoms, R²'s each independently represent a hydrogen atom, an alkyl group having 1 to 6 carbon atoms, or an alkoxyalkyl group having 2 to 10 carbon atoms in total, and R³'s each independently represent an alkyl group having 1 to 6 carbon atoms;
in formula (21), m1 and m2 each independently represent an integer of 1 to 2, when m1 and m2 are each 1, Q represents a single bond, an oxygen atom, or a divalent organic group having 1 to 20 carbon atoms, and when a sum of m1 and m2 is 3 or 4, Q¹ represents a (m1+m2)-valent organic group having 1 to 20 carbon atoms;
in formula (21), n1's each independently represent an integer of 1 to 5, n2's each independently represent an integer of 0 to 4, and n3's each independently represent an integer of 0 to 4, in each benzene ring, n1, n2, and n3 satisfy 1≤(n1+n2+n3)≤5; and
in formula (23), Y represents a monovalent organic group having 1 to 20 carbon atoms.

[8] The composition for forming a resist underlayer film for use in EB or EUV lithography according to [7], wherein the film-forming component contains a polymer that is not the specific structure-containing component.

[9] The composition for forming a resist underlayer film for use in EB or EUV lithography according to any one of [1], to [8], wherein the film-forming component further contains a curing catalyst.

[10] The composition for forming a resist underlayer film for use in EB or EUV lithography according to any one of [1], to [9], wherein the composition is used for forming a resist underlayer film for use in EB or EUV lithography having a film thickness of 10 nm or less.

[11] A resist underlayer film for use in EB or EUV lithography, which is a cured product of the composition for forming a resist underlayer film for use in EB or EUV lithography according to any one of [1] to [10].

[12] A substrate for semiconductor processing including:
a semiconductor substrate; and the resist underlayer film for use in EB or EUV lithography according to [11].

[13] A method for producing a semiconductor element, the method including the steps of:
forming a resist underlayer film on a semiconductor substrate using the composition for forming a resist underlayer film for use in EB or EUV lithography according to any one of [1] to [10]; and forming a resist film on the resist underlayer film using a resist for use in EB or EUV lithography.

[14] A method for forming a pattern, the method including the steps of:
forming a resist underlayer film on a semiconductor substrate using the composition for forming a resist underlayer film for use in EB or EUV lithography according to any one of [1] to [10];
forming a resist film on the resist underlayer film using a resist for use in EB or EUV lithography;
irradiating the resist film with EB or EUV, and then developing the resist film to obtain a resist pattern; and
etching the resist underlayer film using the resist pattern as a mask.

[15] A method for improving LWR of a resist pattern, the method including the steps of:
forming a resist underlayer film on a semiconductor substrate using the composition for forming a resist underlayer film for use in EB or EUV lithography according to any one of [1] to [10];
forming a resist film on the resist underlayer film using a resist for use in EB or EUV lithography; and
irradiating the resist film with EB or EUV, and then developing the resist film to obtain a resist pattern.

### Advantageous Effects of Invention

According to the present invention, it is possible to provide a composition for forming a resist underlayer film for use in EB or EUV lithography, a resist underlayer film for use in EB or EUV lithography, a substrate for semiconductor processing, a method for producing a semiconductor element, a method for forming a pattern, and a method for improving LWR of a resist pattern, with which LWR of a resist pattern in EB or EUV lithography can be improved.

### DESCRIPTION OF EMBODIMENTS

The present inventors studied a method capable of improving LWR by a method other than the rinsing step. As a result, it was found that the composition for forming a resist underlayer film suitable for ArF lithography proposed by the present applicant in WO 2009/075265 A is effective in improving LWR of a resist pattern in EB or EUV lithography.

The composition for forming a resist underlayer film proposed by the present applicant in WO 2009/075265 A plays a role of an antireflection film for preventing the influence of a reflected wave on a resist film when the resist film is exposed in ArF lithography. On the other hand, in EB or EUV lithography, an antireflection film is not necessary because irradiated EB or EUV passes through the substrate. Therefore, it is usually difficult to see any merit in using the composition for forming a resist underlayer film proposed by the present applicant in WO 2009/075265 A for a resist underlayer film for EB or EUV lithography. However, when the composition for forming a resist underlayer film proposed by the present applicant in WO 2009/075265 A was used for a resist underlayer film for EB or EUV lithography, the present inventors found that LWR of a resist pattern can be unexpectedly improved.

Further, as a result of studies, the present inventors found that a group represented by formula (1) below bonded to an aromatic ring or a nitrogen atom in a film-forming component of a composition for forming a resist underlayer film is effective in improving LWR of a resist pattern, and completed the present invention.

(Composition for forming a resist underlayer film for use in EB or EUV lithography)

The composition for forming a resist underlayer film for use in EB or EUV lithography (hereinafter sometimes simply referred to as the “composition for forming a resist underlayer film”) of the present invention contains a film-forming component and a solvent.

### <Film-Forming Component>

The film-forming component contains 20 mass % or more of the specific structure-containing component.

The film-forming component is a component remaining in a resist underlayer film for use in EB or EUV lithography (hereinafter sometimes simply referred to as the “resist underlayer film”) when the resist underlayer film is formed from the composition for forming a resist underlayer film. Examples of the film-forming component include a component present in the resist underlayer film as it is, a component present in the resist underlayer film as a reaction product with another component, and a component used as an auxiliary agent (for example, a curing catalyst) that assists a reaction of another component.

In other words, the film-forming component is a generic term for components other than the solvent among all the components of the composition for forming a resist underlayer film.

The content of the specific structure-containing component in the film-forming component is not particularly limited as long as it is 20 mass % or more. The content of the specific structure-containing component in the film-forming component may be 20 mass % to 100 mass %, or may be 20 mass % to 99.5 mass %.

The content of the specific structure-containing component in the composition for forming a resist underlayer film for use in EB or EUV lithography is not particularly limited as long as the content of the specific structure-containing component in the film-forming component is 20 mass % or more, but when the film-forming component contains a polymer that is not the specific structure-containing component described later, the content is preferably 10 mass % to 90 mass %, more preferably 15 mass % to 70 mass %, and particularly preferably 20 mass % to 50 mass %, with respect to the polymer that is not the specific structure-containing component.

### <<Specific Structure-Containing Component>>

The specific structure-containing component is not particularly limited as long as it contains at least either of a first structure containing an aromatic ring and a second structure containing a nitrogen atom.

The first structure contains a group represented by formula (1) below directly bonded to an aromatic ring.

The second structure contains a group represented by formula (1) below directly bonded to a nitrogen atom.

Hereinafter, “at least either of the first structure containing an aromatic ring and the second structure containing a nitrogen atom” is sometimes referred to as a “specific structure”.

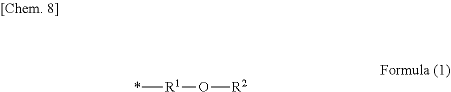

In formula (1), R¹ represents an alkylene group having 1 to 6 carbon atoms, R² represents a hydrogen atom, an alkyl group having 1 to 6 carbon atoms, or an alkoxyalkyl group having 2 to 10 carbon atoms in total, and * represents a bond.

The alkylene group having 1 to 6 carbon atoms in the present invention may be in any of a linear form, a branched form, and a cyclic form. Examples of the alkylene group having 1 to 6 carbon atoms include an alkylene group having 1 to 4 carbon atoms.

Examples of the alkylene group having 1 to 6 carbon atoms include a methylene group, a 1,2-ethylene group, a 1,1-ethylene group, a 1,2-propylene group, a 1,3-propylene group, a tetramethylene group, a 1-methyl-1,3-propylene group, a 2-methyl-1,3-propylene group, a 2-methyl-1,2-propylene group, a pentamethylene group, a hexamethylene group, a 1,3-cyclohexylene group, and a 1,4-cyclohexylene group.

Among them, from the viewpoint of suitably obtaining the effect of the present invention, an alkylene group having 1 to 4 carbon atoms is preferred, and a methylene group is more preferred.

The alkyl group having 1 to 6 carbon atoms in the present invention may be in any of a linear form, a branched form, and a cyclic form. Examples of the alkyl group having 1 to 6 carbon atoms include an alkyl group having 1 to 4 carbon atoms.

Examples of the alkyl group having 1 to 6 carbon atoms include a methyl group, an ethyl group, a n-propyl group, an iso-propyl group, a cyclopropyl group, a n-butyl group, an iso-butyl group, a sec-butyl group, a tert-butyl group, a cyclobutyl group, a 1-methyl-cyclopropyl group, a 2-methyl-cyclopropyl group, a n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group.

Among them, from the viewpoint of suitably obtaining the effect of the present invention, an alkyl group having 1 to 4 carbon atoms is preferred, and a methyl group is more preferred.

Examples of the alkoxyalkyl group having 2 to 10 carbon atoms in total in the present invention include a methoxymethyl group, a 1-methoxyethyl group, a 2-methoxyethyl group, a 1-methoxypropyl group, a 2-methoxypropyl group, a 3-methoxypropyl group, a 1-methoxy-1-methylethyl group, a 2-methoxy-1-methylethyl group, an ethoxymethyl group, a 1-ethoxyethyl group, a 2-ethoxyethyl group, a 1-ethoxypropyl group, a 2-ethoxypropyl group, a 3-ethoxypropyl group, a 1-ethoxy-1-methylethyl group, a 2-ethoxy-1-methylethyl group, a propoxymethyl group, a 1-propoxyethyl group, a 2-propoxyethyl group, a 1-propoxy-1-methylethyl group, a 2-propoxy-1-methylethyl group, an isopropoxymethyl group, a 1-isopropoxyethyl group, a 2-isopropoxyethyl group, a butoxymethyl group, a sec-butoxymethyl group, an isobutoxymethyl group, and a tert-butoxymethyl group.

The number of carbon atoms in the alkoxy group in the alkoxyalkyl group is preferably 1 to 6, and more preferably 1 to 4.

The number of carbon atoms in the alkylene group in the alkoxyalkyl group is preferably 1 to 4, and more preferably 1 to 2.

Among them, from the viewpoint of suitably obtaining the effect of the present invention, a 2-methoxy-1-methylethyl group is preferred.

### <<<Polymer as Specific Structure-Containing Component>>>

The specific structure-containing component includes, for example, a polymer containing a specific structure.

The polymer containing a specific structure preferably contains, as the first structure, at least any of a structure represented by formula (11) below, a structure represented by formula (12) below, and a structure represented by formula (13) below.

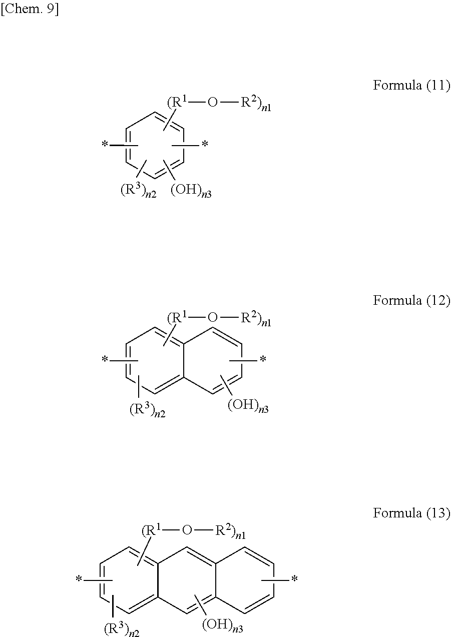

In formula (11) to formula (13), R¹'s each independently represent an alkylene group having 1 to 6 carbon atoms, R²'s each independently represent a hydrogen atom, an alkyl group having 1 to 6 carbon atoms, or an alkoxyalkyl group having 2 to 10 carbon atoms in total, R³'s each independently represent an alkyl group having 1 to 6 carbon atoms, and * represents a bond;
in formula (11), n1 represents an integer of 1 to 4, n2 represents an integer of 0 to 3, n3 represents an integer of 0 to 3, and n1, n2, and n3 satisfy 1≤(n1+n2+n3)≤4;
in formula (12), n1 represents an integer of 1 to 6, n2 represents an integer of 0 to 5, n3 represents an integer of 0 to 5, and n1, n2, and n3 satisfy 1≤(n1+n2+n3)≤6;
in formula (13), n1 represents an integer of 1 to 8, n2 represents an integer of 0 to 7, n3 represents an integer of 0 to 7, and n1, n2, and n3 satisfy 1≤(n1+n2+n3)≤8;
in formula (11) to formula (13), when there are two or more R¹'s, the two or more R¹'s may be identical or different, when there are two or more R²'s, the two or more R²'s may be identical or different, and when there are two or more R³'s, the two or more R³'s may be identical or different.

In formula (11), n1 is preferably an integer of 2 to 3, and more preferably 2.

In formula (12), n1 is preferably an integer of 2 to 4, and more preferably 2.

In formula (13), n1 is preferably an integer of 2 to 6, and more preferably 2.

In formula (11), n2 is preferably an integer of 0 to 1, and more preferably 0.

In formula (12), n2 is preferably an integer of 0 to 3, and more preferably 0.

In formula (13), n2 is preferably an integer of 0 to 5, and more preferably 0.

In formula (11), n3 is preferably an integer of 0 to 1, and more preferably 1.

In formula (12), n3 is preferably an integer of 0 to 3, and more preferably 1.

In formula (13), n3 is preferably an integer of 0 to 5, and more preferably 1.

The polymer containing a specific structure preferably includes at least either of a repeating unit represented by formula (11-1) below and a repeating unit represented by formula (11-2) below as a repeating unit containing a structure represented by formula (11).

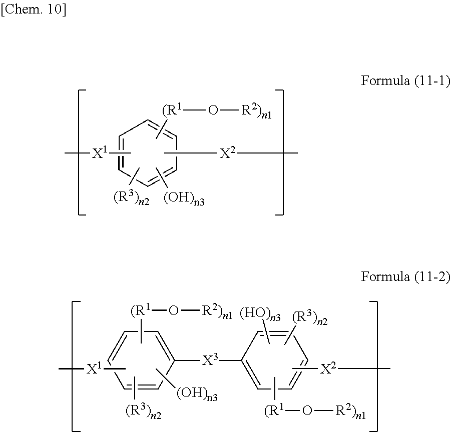

In formula (11-1) and formula (11-2), R¹'s each independently represent an alkylene group having 1 to 6 carbon atoms, R²'s each independently represent a hydrogen atom, an alkyl group having 1 to 6 carbon atoms, or an alkoxyalkyl group having 2 to 10 carbon atoms in total, R³'s each independently represent an alkyl group having 1 to 6 carbon atoms, n1's each independently represent an integer of 1 to 4, n2's each independently represent an integer of 0 to 3, and n3's each independently represent an integer of 0 to 3;
in formula (11-1), X¹ and X² each independently represent a single bond, an oxygen atom, or a methylene group;
in formula (11-2), X¹ and X² each independently represent a single bond, an oxygen atom, or a methylene group, and X³ represents a single bond or a divalent organic group having 1 to 15 carbon atoms;
in formula (11-1), n1, n2, and n3 satisfy 1≤(n1+n2+n3)≤4;
in formula (11-2), n1, n2, and n3 in a benzene ring on a left side satisfy 1≤(n1+n2+n3) S 4, and n1, n2, and n3 in a benzene ring on a right side satisfy 1≤(n1+n2+n3) S 4; and
in formula (11-1) and formula (11-2), when there are two or more R¹'s, the two or more R¹'s may be identical or different, when there are two or more R²'s, the two or more R²'s may be identical or different, and when there are two or more R³'s, the two or more R³'s may be identical or different.

Preferred embodiments of n1, n2, and n3 in formula (11-1) are the same as the preferred embodiments of n1, n2, and n3 in formula (11), respectively.

Preferred embodiments of n1, n2, and n3 in the benzene ring on the left side and preferred embodiments of n1, n2, and n3 in the benzene ring on the right side in formula (11-2) are the same as the preferred embodiments of n1, n2, and n3 in formula (11), respectively.

Examples of the divalent organic group having 1 to 15 carbon atoms in X³ in formula (11-2) include a divalent organic group represented by formula (11-2-1) below.

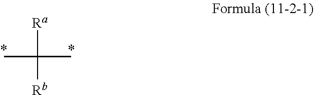

In formula (11-2-1), R^{a} and R^{b} each independently represent a hydrogen atom, an alkyl group having up to 6 carbon atoms, or —CF₃, and * represents a bond.

The polymer having a specific structure preferably further contains a repeating unit represented by formula (14) below.

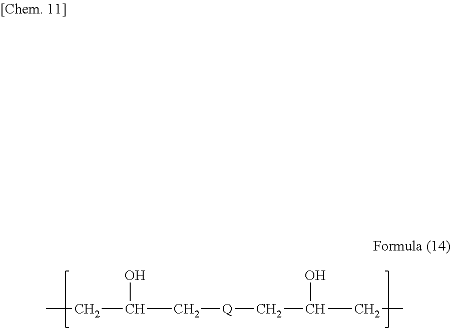

The polymer containing a specific structure preferably includes a repeating unit represented by formula (15) below in which a repeating unit represented by formula (14) and a repeating unit represented by formula (11-1) are combined.

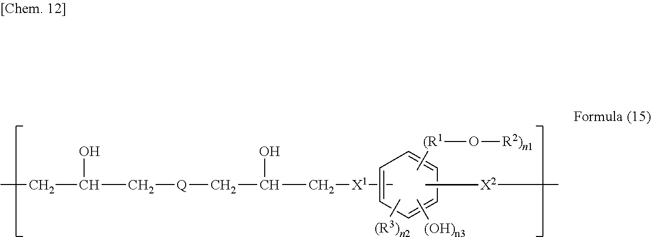

R¹, R², R³, n1, n2, n3, X¹, X², and Q in formula (15) are the same as R¹, R², R³, n1, n2, n3, X¹, X², and Q in formula (11-1) and formula (14), respectively. Specific examples and preferred examples are also the same.

In formula (14), Q preferably represents a divalent group represented by formula (14-1) below or an arylene group having 6 to 40 carbon atoms from the viewpoint of suitably obtaining the effect of the present invention.

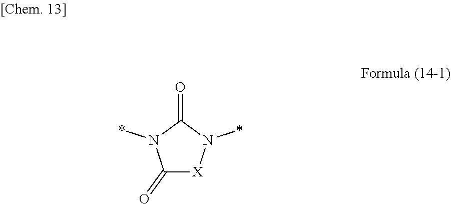

In formula (14-1), X represents a group represented by any of formulae (14-1a) to (14-1c) below.

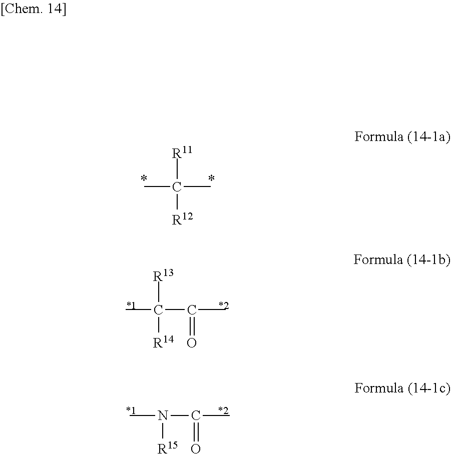

In formulae (14-1a) to (14-1c), R¹¹, R¹², R¹³, R¹⁴, and R¹⁵ each independently represent a hydrogen atom, an alkyl group having 1 to 6 carbon atoms, an alkenyl group having 3 to 6 carbon atoms, a benzyl group, or a phenyl group, and the benzyl group and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms, R¹¹ and R¹² may be bonded to each other to form a ring having 3 to 6 carbon atoms, R¹³ and R¹⁴ may be bonded to each other to form a ring having 3 to 6 carbon atoms, * represents a bond, *1 represents a bond bonded to a carbon atom, and *2 represents a bond bonded to a nitrogen atom.

Examples of the alkoxy group having 1 to 6 carbon atoms in the present invention include a methoxy group, an ethoxy group, a n-propoxy group, an iso-propoxy group, a n-butoxy group, an iso-butoxy group, a sec-butoxy group, a tert-butoxy group, a n-pentyloxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, a n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, and a 1-ethyl-2-methyl-n-propoxy group.

Examples of the alkylthio group having 1 to 6 carbon atoms in the present invention include a methylthio group, an ethylthio group, a propylthio group, an isopropylthio group, a butylthio group, an isobutylthio group, a sec-butylthio group, a tert-butylthio group, a pentylthio group, and a hexylthio group.

The arylene group having 6 to 40 carbon atoms, which is an example of Q, may have a substituent in the aromatic ring. Examples of the substituent include a halogen atom, a nitro group, a cyano group, an alkyl group having 1 to 6 carbon atoms, and an alkylene group having 1 to 6 carbon atoms. The number of substituents in the aromatic ring may be one or more.

Examples of the arylene group having 6 to 40 carbon atoms include a divalent group obtained by removing one hydrogen atom from an aromatic ring of any monovalent group of a phenyl group, an o-methylphenyl group, a m-methylphenyl group, a p-methylphenyl group, an o-chlorophenyl group, a m-chlorophenyl group, a p-chlorophenyl group, an o-fluorophenyl group, a p-fluorophenyl group, an o-methoxyphenyl group, a p-methoxyphenyl group, a p-nitrophenyl group, a p-cyanophenyl group, an a-naphthyl group, and a p-naphthyl group; a 4,4′-biphenylene group; and a divalent group obtained by removing two hydrogen atoms from either of anthracene and phenanthrene.

The molecular weight of the polymer containing a specific structure is not particularly limited, but the weight average molecular weight by gel permeation chromatography is preferably 1,500 to 100,000, and more preferably 2,000 to 50,000.

The content of the polymer containing a specific structure in the composition for forming a resist underlayer film for use in EB or EUV lithography is not particularly limited as long as the content of the specific structure-containing component in the film-forming component is 20 mass % or more, but may be 20 mass- to 100 mass % or 20 mass % to 99.5 mass % with respect to the film-forming component.

The content of the polymer containing a specific structure in the composition for forming a resist underlayer film for use in EB or EUV lithography is not particularly limited as long as the content of the specific structure-containing component in the film-forming component is 20 mass- or more, but when the film-forming component contains a polymer that is not the specific structure-containing component described later, the content is preferably 10 mass % to 90 mass %, more preferably 15 mass to 70 mass %, and particularly preferably 20 mass % to 50 mass % with respect to the polymer that is not the specific structure-containing component.

### <<<Crosslinking Agent as Specific Structure-Containing Component>>>

The specific structure-containing component contains, for example, a crosslinking agent containing a specific structure.

The crosslinking agent containing a specific structure preferably contains at least any of a compound represented by formula (21) below, a compound represented by formula (22) below, and a compound represented by formula (23) below.

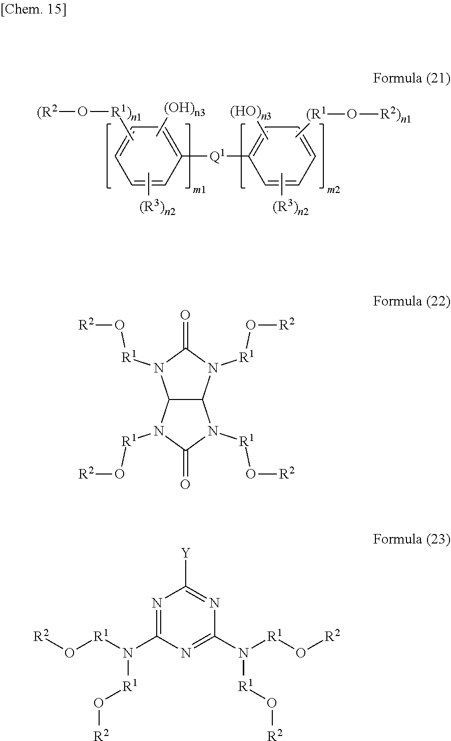

In formula (21) to formula (23), R¹'s each independently represent an alkylene group having 1 to 6 carbon atoms, R²'s each independently represent a hydrogen atom, an alkyl group having 1 to 6 carbon atoms, or an alkoxyalkyl group having 2 to 10 carbon atoms in total, and R³'s each independently represent an alkyl group having 1 to 6 carbon atoms;
in formula (21), m1 and m2 each independently represent an integer of 1 to 2, when m1 and m2 are each 1, Q¹ represents a single bond, an oxygen atom, or a divalent organic group having 1 to 20 carbon atoms, and when a sum of m1 and m2 is 3 or 4, Q¹ represents a (m1+m2)-valent organic group having 1 to 20 carbon atoms;
in formula (21), n1's each independently represent an integer of 1 to 5, n2's each independently represent an integer of 0 to 4, and n3's each independently represent an integer of 0 to 4, in each benzene ring, n1, n2, and n3 satisfy 1≤(n1+n2+n3)≤5; and
in formula (23), Y represents a monovalent organic group having 1 to 20 carbon atoms.

Examples of the (m1+m2)-valent organic group having 1 to 20 carbon atoms in Q¹ include groups represented by any of formula (21-1) to formula (21-5) below.

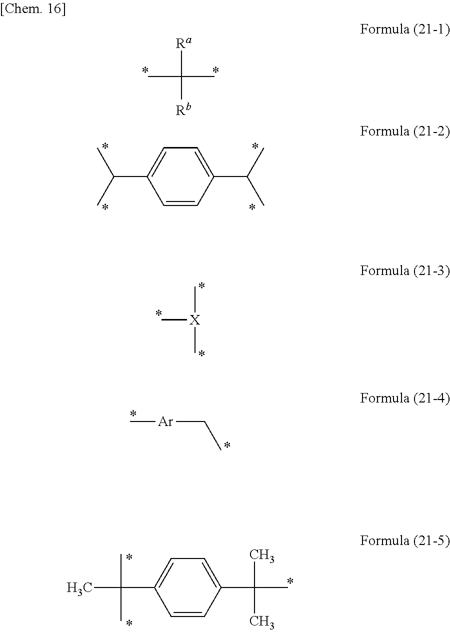

In formula (21-1), R^{a} and R^{b} each independently represent a hydrogen atom, an alkyl group having 1 to 4 carbon atoms, or a —CF₃ group.

In formula (21-3), X represents a trivalent group having 1 to 30 carbon atoms.

In formula (21-4), Ar represents a divalent aromatic hydrocarbon group.

* represents a bond.

Ar represents, for example, a divalent residue of a compound selected from benzene, biphenyl, naphthalene, and anthracene.

The group represented by formula (21-1) is a divalent group.

The group represented by formula (21-2) is a tetravalent group.

The group represented by formula (21-3) is a trivalent group.

The group represented by formula (21-4) is a divalent group.

The group represented by formula (21-5) is a trivalent group.

Examples of the monovalent organic group having 1 to 20 carbon atoms in Y include a phenyl group and a group represented by formula (23-1) below.

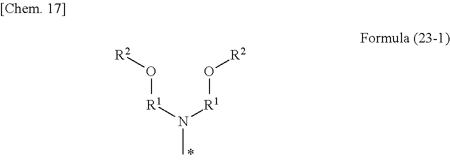

In formula (23-1), R¹'s each independently represent an alkylene group having 1 to 6 carbon atoms, R²'s each independently represent a hydrogen atom, an alkyl group having 1 to 6 carbon atoms, or an alkoxyalkyl group having 2 to 10 carbon atoms in total, and * represents a bond.

Specific examples and preferred examples of R¹ and R² in formula (23-1) include specific examples and preferred examples of R¹ and R² in formula (1).

The molecular weight of the crosslinking agent containing a specific structure is not particularly limited, but is preferably less than 1,500, and more preferably 1,000 or less.

The content of the crosslinking agent containing a specific structure in the composition for forming a resist underlayer film for use in EB or EUV lithography is not particularly limited as long as the content of the specific structure-containing component in the film-forming component is 20 mass % or more, but may be 20 mass % to 100 mass % or 20 mass % to 99.5 mass % with respect to the film-forming component.

The content of the crosslinking agent containing a specific structure in the composition for forming a resist underlayer film for use in EB or EUV lithography is not particularly limited as long as the content of the specific structure-containing component in the film-forming component is 20 mass % or more, but when the film-forming component contains a polymer that is not the specific structure-containing component described later, the content is preferably 10 mass % to 90 mass %, more preferably 15 mass %, to 70 mass %, and particularly preferably 20 mass to 50 mass % with respect to the polymer that is not the specific structure-containing component.

<<Polymer that is not Specific Structure-Containing Component>>

The film-forming component may contain a polymer that is not the specific structure-containing component. The polymer does not contain a specific structure.

Such a polymer is not particularly limited, and examples thereof include a reaction product of an epoxy resin represented by general formula (3) below described in JP 2007-262013 A with a diamine compound.

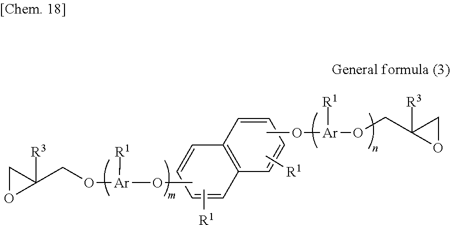

In general formula (3), R³ represents a hydrogen atom or a methyl group, Ar's each independently represent a naphthylene group, a phenylene group, or a naphthylene group or a phenylene group having an alkyl group with 1 to 4 carbon atoms or a phenyl group as a substituent, R²'s each independently represent a hydrogen atom or an alkyl group having 1 to 4 carbon atoms, n and m are each an integer of 0 to 2, and either of n and m is 1 or more, and R represents a hydrogen atom or an epoxy group-containing aromatic hydrocarbon group represented by general formula (3-2) below. However, the total number of aromatic nuclei in the formula is 2 to 8. In general formula (3), the bonding position to the naphthalene skeleton may be either of two rings forming a naphthalene ring.

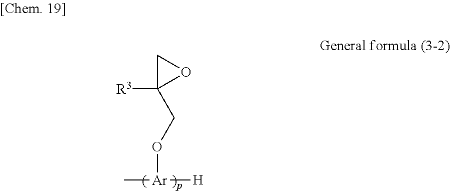

In general formula (3-2), R³ represents a hydrogen atom or a methyl group, Ar's each independently represent a trivalent group obtained by removing three hydrogen atoms from a naphthalene ring, a trivalent group obtained by removing three hydrogen atoms from a benzene ring, or a trivalent group obtained by removing three hydrogen atoms from a naphthalene ring or a trivalent group obtained by removing three hydrogen atoms from a benzene ring having an alkyl group with 1 to 4 carbon atoms or a phenyl group as a substituent, and p is an integer of 1 or 2.

Examples of the diamine compound include compounds represented by formula (4) below.

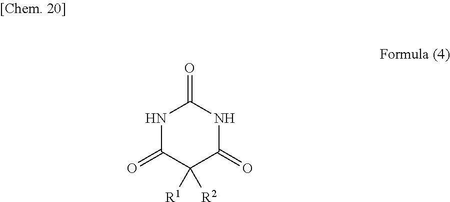

In formula (4), R¹ and R² are each independently a hydrogen atom, an alkyl group having 1 to 6 carbon atoms, an alkenyl group having 3 to 6 carbon atoms, a benzyl group, or a phenyl group, the phenyl group may be substituted with at least one kind of group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms, and R¹ and R² may be bonded to each other to form a ring having 3 to 6 carbon atoms together with the carbon atom to which R¹ and R² are bonded.

Examples of the polymer that is not the specific structure-containing component include a novolak resin containing a halogen atom. Examples of the novolak resin containing a halogen atom include novolak resins containing a halogen atom described in WO 2010/122948 A.

Examples of the polymer that is not the specific structure-containing component include a polymer having a repeating unit structure represented by formula (1A) below. Examples of the polymer include polymers described in WO 2011/074494 A.

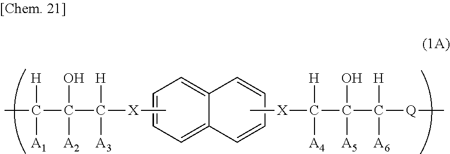

In formula (1A), X represents an ester bond or an ether bond, A₁, A₂, A₃, A₄, A₅, and A₆ each represent a hydrogen atom, a methyl group, or an ethyl group, and Q represents a group represented by formula (2A) or formula (3A) below.

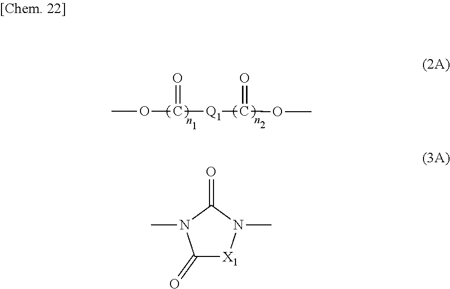

In formulae (2A) and (3A), Q₁ represents an alkylene group having 1 to 10 carbon atoms, a phenylene group, a naphthylene group, or an anthrylene group, and each of the phenylene group, the naphthylene group, and the anthrylene group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms, n₁ and n₂ each represent a number of 0 or 1, and X₁ represents a group represented by formula (4A), formula (5A), or formula (6A) below.

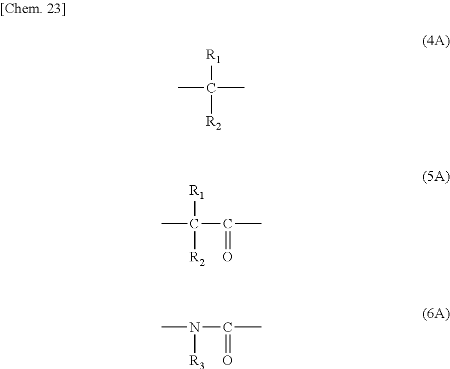

In formulae (4A) to (6A), R₁ and R₂ each represent a hydrogen atom, an alkyl group having 1 to 6 carbon atoms, an alkenyl group having 2 to 6 carbon atoms, a benzyl group, or a phenyl group, the benzyl group and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms, R₁ and R₂ may be bonded to each other to form a ring having 3 to 6 carbon atoms, R₃ represents an alkyl group having 1 to 6 carbon atoms, an alkenyl group having 2 to 6 carbon atoms, a benzyl group, or a phenyl group, and the benzyl group and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms.

Examples of the polymer that is not the specific structure-containing component include a polymer in which diphenyl sulfone or a derivative thereof is introduced into the main chain via an ether bond. Examples of the polymer include polymers described in WO 2012/067040 A.

Examples of the polymer that is not the specific structure-containing component include polymers having structural units represented by formula (1B) and formula (2B) below. Examples of the polymer include polymers described in WO 2012/081619 A.

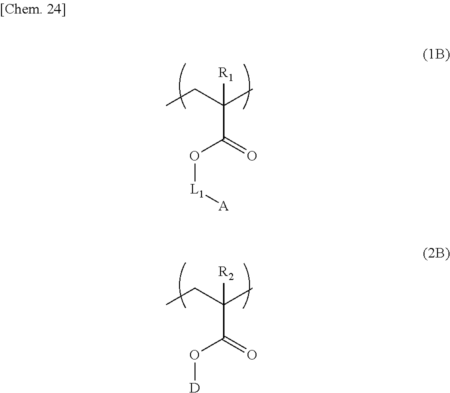

In formulae (1B) and (2B), R₁ and R₂ each independently represent a hydrogen atom or a methyl group, L₁ represents a single bond or a divalent linking group having a linear or branched alkylene group having 1 to 13 carbon atoms, A represents an aromatic ring group having at least one substituent containing a hydroxy group, and D represents a linear or branched hydroxyalkyl group having 1 to 13 carbon atoms.

Examples of the polymer that is not the specific structure-containing component include a polymer having a repeating unit structure represented by formula (1C) below. Examples of the polymer include polymers described in WO 2013/018802 A.

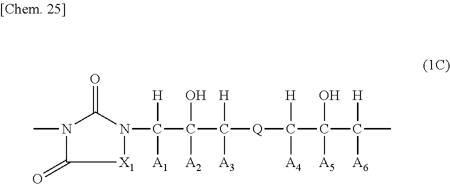

In formula (1C), A₁, A₂, A₃, A₄, A₅, and A₆ each represent a hydrogen atom, a methyl group, or an ethyl group, X₁ represents formula (2C), formula (3C), formula (4C), or formula (0C) below, and Q represents formula (5C) or formula (6C) below.

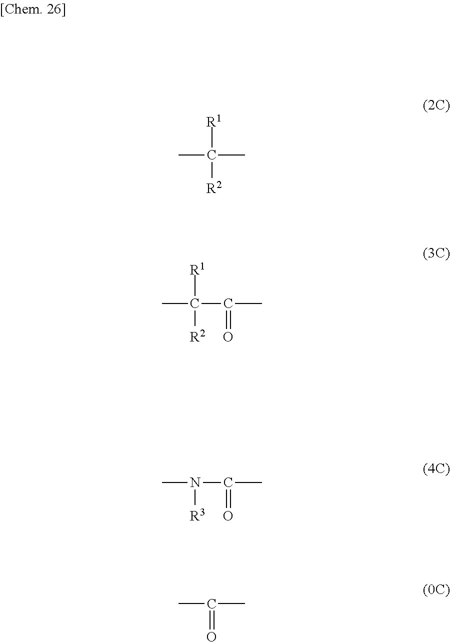

In formulae (2C) to (4C) and (0C), R₁ and R₂ each represent a hydrogen atom, a halogen atom, an alkyl group having 1 to 6 carbon atoms, an alkenyl group having 3 to 6 carbon atoms, a benzyl group, or a phenyl group, the alkyl group having 1 to 6 carbon atoms, the alkenyl group having 3 to 6 carbon atoms, the benzyl group, and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, a carboxyl group, and an alkylthio group having 1 to 6 carbon atoms, R₁ and R₂ may be bonded to each other to form a ring having 3 to 6 carbon atoms, R₃ represents a halogen atom, an alkyl group having 1 to 6 carbon atoms, an alkenyl group having 3 to 6 carbon atoms, a benzyl group, or a phenyl group, and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms.

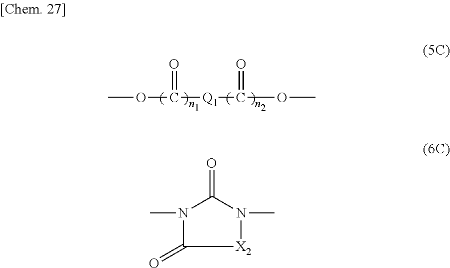

In formulae (5C) and (6C), Q, represents an alkylene group having 1 to 10 carbon atoms, a phenylene group, a naphthylene group, or an anthrylene group, and each of the alkylene group, the phenylene group, the naphthylene group, and the anthrylene group may be substituted with an alkyl group having 1 to 6 carbon atoms, a carbonyloxyalkyl group having 2 to 7 carbon atoms, a halogen atom, an alkoxy group having 1 to 6 carbon atoms, a phenyl group, a nitro group, a cyano group, a hydroxy group, an alkylthio group having 1 to 6 carbon atoms, a group having a disulfide group, a carboxyl group, or a group formed of a combination thereof, n₁ and n₂ each represent a number of 0 or 1, and X₂ represents formula (2C), formula (3C), or formula (0C).

Examples of the polymer that is not the specific structure-containing component include a polymer having a structure represented by formula (1D) or formula (2D) below at the terminal of the polymer chain. Examples of the polymer include polymers described in WO 2015/163195 A.

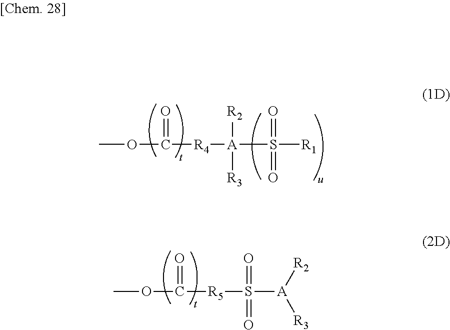

In formulae (1D) and (2D), R₁ represents an alkyl group having 1 to 6 carbon atoms, which may have a substituent, a phenyl group, a pyridyl group, a halogeno group, or a hydroxy group, R₂ represents a hydrogen atom, an alkyl group having 1 to 6 carbon atoms, a hydroxy group, a halogeno group, or an ester group represented by —C(═O)O—X, where X represents an alkyl group having 1 to 6 carbon atoms, which may have a substituent, R₃ represents a hydrogen atom, an alkyl group having 1 to 6 carbon atoms, a hydroxy group, or a halogeno group, R₄ represents a direct bond or a divalent organic group having 1 to 8 carbon atoms, R₅ represents a divalent organic group having 1 to 8 carbon atoms, A represents an aromatic ring or an aromatic heterocyclic ring, t represents 0 or 1, and u represents 1 or 2.

Examples of the polymer that is not the specific structure-containing component include a polymer containing an aliphatic ring in which a carbon-carbon bond may be interrupted by a heteroatom and also may be substituted with a substituent at the terminal. Examples of the polymer include polymers described in WO 2020/226141 A.

The molecular weight of the polymer that is not the specific structure-containing component is not particularly limited, but the weight average molecular weight by gel permeation chromatography (hereinafter sometimes abbreviated as GPC) is preferably 1,500 to 100,000, and more preferably 2,000 to 50,000.

When the film-forming component contains the polymer that is not the specific structure-containing component, the content of the polymer that is not the specific structure-containing component in the composition for forming a resist underlayer film for use in EB or EUV lithography is not particularly limited, but is preferably 30 mass % or more and less than 80 mass %, more preferably 50 mass % or more and less than 80 mass %, and particularly preferably 60 mass % or more and less than 80 masse with respect to the film-forming component.

### <<Curing Catalyst>>

As the curing catalyst contained as an optional component in the composition for forming a resist underlayer film, either of a thermal acid generator and a photoacid generator can be used, but it is preferred to use a thermal acid generator.

Examples of the thermal acid generator include sulfonic acid compounds and carboxylic acid compounds such as p-toluenesulfonic acid, trifluoromethanesulfonic acid, pyridinium p-toluenesulfonate (pyridinium p-toluenesulfonic acid), pyridinium phenolsulfonate, pyridinium p-hydroxybenzenesulfonate (p-phenolsulfonic acid pyridinium salt), pyridinium trifluoromethanesulfonate, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photoacid generator include an onium salt compound, a sulfonimide compound, and a disulfonyl diazomethane compound.

Examples of the onium salt compound include iodonium salt compounds such as diphenyliodonium hexafluorophosphate, diphenyliodonium trifluoromethanesulfonate, diphenyliodonium nonafluoronormalbutanesulfonate, diphenyliodonium perfluoronormaloctanesulfonate, diphenyliodonium camphorsulfonate, bis(4-tert-butylphenyl)iodonium camphorsulfonate, and bis(4-tert-butylphenyl)iodonium trifluoromethanesulfonate, and sulfonium salt compounds such as triphenylsulfonium hexafluoroantimonate, triphenylsulfonium nonafluoronormalbutanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoronormalbutanesulfonyloxy)succinimide, N-(camphorsulfonyloxy)succinimide, and N-(trifluoromethanesulfonyloxy)naphthalimide.

Examples of the disulfonyl diazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl p-toluenesulfonyl diazomethane.

Only one kind of curing catalyst can be used, or two or more kinds thereof can be used in combination.

When a curing catalyst is used, the content ratio of the curing catalyst is, for example, 0.1 masse to 50 mass %, preferably 1 mass % to 30 mass % with respect to the specific structure-containing component.

### <<Other Components>>

In the composition for forming a resist underlayer film, a surfactant can be further added in order to further improve the coating property against surface unevenness without formation of pinholes, striations, or the like.

Examples of the surfactant include nonionic surfactants including polyoxyethylene alkyl ethers such as polyoxyethylene lauryl ether, polyoxyethylene stearyl ether, polyoxyethylene cetyl ether, and polyoxyethylene oleyl ether, polyoxyethylene alkyl allyl ethers such as polyoxyethylene octylphenol ether and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, fluorine-based surfactants such as EFTOP EF301, EF303, and EF352 (trade name, manufactured by Tochem Products Co., Ltd.), MEGAFAC F171, F173, and R-30 (trade name, manufactured by DIC Corporation), Fluorad FC430 and FC431 (trade name, manufactured by Sumitomo 3M Limited), Asahi Guard AG710, Surflon S-382, SC101, SC102, SC103, SC104, SC105, and SC106 (trade name, manufactured by Asahi Glass Co., Ltd.), and an organosiloxane polymer KP341 (manufactured by Shin-Etsu Chemical Co., Ltd.).

The blending amount of such a surfactant is not particularly limited, but is usually 2.0 mass % or less, and preferably 1.0 mass % or less with respect to the total solid content of the composition for forming a resist underlayer film.

These surfactants may be added alone, or two or more kinds thereof may be added in combination.

The film-forming component contained in the composition for forming a resist underlayer film, that is, the component excluding the solvent is, for example, 0.01 mass % to 10 masse of the composition for forming a resist underlayer film.

### <Solvent>

As the solvent, an organic solvent generally used for a chemical solution for a semiconductor lithography process is preferred. Specific examples thereof include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxy cyclopentane, anisole, y-butyrolactone, N-methylpyrrolidone, N,N-dimethylformamide, and N,N-dimethylacetamide. These solvents can be used alone, or two or more kinds thereof can be used in combination.

Among these solvents, propylene glycol monomethyl ether, propylene glycol monomethyl ether acetate, ethyl lactate, butyl lactate, and cyclohexanone are preferred. In particular, propylene glycol monomethyl ether and propylene glycol monomethyl ether acetate are preferred.

The composition for forming a resist underlayer film for use in EB or EUV lithography is preferably used for forming a resist underlayer film for use in EB or EUV lithography having a film thickness of 10 nm or less.

### (Resist Underlayer Film for Use in EB or EUV Lithography)

The resist underlayer film for use in EB or EUV lithography (hereinafter sometimes simply referred to as the “resist underlayer film”) of the present invention is a cured product of the composition for forming a resist underlayer film for use in EB or EUV lithography.

The resist underlayer film can be produced, for example, by applying the composition for forming a resist underlayer film for use in EB or EUV lithography onto a semiconductor substrate and firing the composition.

Examples of the semiconductor substrate to which the composition for forming a resist underlayer film is applied include a silicon wafer, a germanium wafer, and a compound semiconductor wafer of gallium arsenide, indium phosphide, gallium nitride, indium nitride, aluminum nitride, or the like.

When a semiconductor substrate having an inorganic film formed on a surface thereof is used, the inorganic film is formed by, for example, an atomic layer deposition (ALD) method, a chemical vapor deposition (CVD) method, a reactive sputtering method, an ion plating method, a vacuum deposition method, or a spin coating method (spin-on glass: SOG). Examples of the inorganic film include a polysilicon film, a silicon oxide film, a silicon nitride film, a boro-phospho silicate glass (BPSG) film, a titanium nitride film, a titanium nitride oxide film, a tungsten film, a gallium nitride film, and a gallium arsenide film.

The composition for forming a resist underlayer film of the present invention is applied onto such a semiconductor substrate by an appropriate application method such as a spinner or a coater. Thereafter, the composition is baked using a heating unit such as a hot plate to form a resist underlayer film. The baking conditions are appropriately selected from the baking temperature of 100° C. to 400° C. and from the baking time of 0.3 minutes to 60 minutes. It is preferred that the baking temperature is 120° C. to 350° C. and the baking time is 0.5 minutes to 30 minutes, and it is more preferred that the baking temperature is 150° C. to 300° C. and the baking time is 0.8 minutes to 10 minutes.

The film thickness of the resist underlayer film is preferably 10 nm or less, more preferably 9 nm or less, still more preferably 8 nm or less, and particularly preferably 7 nm or less from the viewpoint of suitably obtaining the effect of the present invention. The film thickness of the resist underlayer film may be 1 nm or more, or 2 nm or more, or 3 nm or more.

The film thickness of the resist underlayer film is, for example, 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (3 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), 0.005 μm (5 nm) to 0.02 μm (20 nm), 0.005 μm (5 nm) to 0.02 μm (20 nm), 0.003 μm (3 nm) to 0.01 μm (10 nm), 0.005 μm (5 nm) to 0.01 μm (10 nm), 0.003 μm (3 nm) to 0.006 μm (6 nm), or 0.005 μm (5 nm).

The method of measuring the film thickness of the resist underlayer film in the present description is as follows.
Measuring device name: ellipsometric film thickness measurement system RE-3100 (SCREEN Semiconductor Solutions Co., Ltd.)
Single wavelength ellipsometer (SWE) mode
Arithmetic average of measurements at 8 points (for example, measurement is made at 8 points at intervals of 1 cm in X direction of wafer)

### (Substrate for Semiconductor Processing)

The substrate for semiconductor processing of the present invention includes a semiconductor substrate and the resist underlayer film for use in EB or EUV lithography of the present invention.

Examples of the semiconductor substrate include semiconductor substrates described above.

The resist underlayer film is disposed, for example, on the semiconductor substrate.

### (Method for Producing Semiconductor Element, Method for Forming Pattern, and Method for Improving LWR of Resist Pattern)

The method for producing a semiconductor element of the present invention includes at least the following steps.
a step of forming a resist underlayer film on a semiconductor substrate using the composition for forming a resist underlayer film for use in EB or EUV lithography of the present invention, and
a step of forming a resist film on the resist underlayer film using a resist for use in EB or EUV lithography

The method for forming a pattern of the present invention includes at least the following steps.
a step of forming a resist underlayer film on a semiconductor substrate using the composition for forming a resist underlayer film for use in EB or EUV lithography of the present invention,
a step of forming a resist film on the resist underlayer film using a resist for use in EB or EUV lithography,
a step of irradiating the resist film with EB or EUV, and then developing the resist film to obtain a resist pattern, and
a step of etching the resist underlayer film using the resist pattern as a mask

The method for improving LWR of a resist pattern of the present invention includes at least the following steps.
a step of forming a resist underlayer film on a semiconductor substrate using the composition for forming a resist underlayer film for use in EB or EUV lithography of the present invention,
a step of forming a resist film on the resist underlayer film using a resist for use in EB or EUV lithography, and
a step of irradiating the resist film with EB or EUV, and then developing the resist film to obtain a resist pattern

In the method for improving LWR of a resist pattern, use of a resist underlayer film obtained from the composition for forming a resist underlayer film for use in EB or EUV lithography of the present invention under a resist film can improve non-uniformity of a width of a resist pattern (line width roughness: LWR) in EB or EUV lithography.

Usually, a resist film is formed on the resist underlayer film.

The film thickness of the resist film is preferably 200 nm or less, more preferably 150 nm or less, still more preferably 100 nm or less, and particularly preferably 80 nm or less. Further, the film thickness of the resist film is preferably 10 nm or more, more preferably 20 nm or more, and particularly preferably 30 nm or more.

A resist formed on the resist underlayer film by application and firing using a known method is not particularly limited as long as the resist responds to EB or EUV used for irradiation. Both a negative photoresist and a positive photoresist can be used.

In the present description, a resist responding to EB is also referred to as a photoresist.

Examples of the photoresist include a positive photoresist made of a novolak resin and 1,2-naphthoquinonediazide sulfonic acid ester, a chemically amplified photoresist made of a binder having a group, which is decomposed by an acid to increase the alkali dissolution rate, and a photoacid generator, a chemically amplified photoresist made of a low molecular compound, which is decomposed by an acid to increase the alkali dissolution rate of the photoresist, an alkali-soluble binder, and a photoacid generator, a chemically amplified photoresist made of a binder having a group, which is decomposed by an acid to increase the alkali dissolution rate, a low molecular compound, which is decomposed by an acid to increase the alkali dissolution rate of the photoresist, and a photoacid generator, and a resist containing a metal element. Examples thereof include V146G (trade name) manufactured by JSR Corporation, APEX-E (trade name) manufactured by Shipley Company, Inc., PAR710 (trade name) manufactured by Sumitomo Chemical Co., Ltd., and AR2772 and SEPR430 (trade names) manufactured by Shin-Etsu Chemical Co., Ltd. Further, examples thereof include fluorine atom-containing polymer-based photoresists as described in Proc. SPIE, Vol. 3999, 330-334 (2000), Proc. SPIE, Vol. 3999, 357-364 (2000), and Proc. SPIE, Vol. 3999, 365-374 (2000).

Further, a resist composition, a radiation-sensitive resin composition, a so-called resist composition such as a high-resolution patterning composition based on an organometallic solution, and a metal-containing resist composition described in the following documents can be used, but not limited thereto: WO 2019/188595 A, WO 2019/187881 A, WO 2019/187803 A, WO 2019/167737 A, WO 2019/167725 A, WO 2019/187445 A, WO 2019/167419 A, WO 2019/123842 A, WO 2019/054282 A, WO 2019/058945 A, WO 2019/058890 A, WO 2019/039290 A, WO 2019/044259 A, WO 2019/044231 A, WO 2019/026549 A, WO 2018/193954 A, WO 2019/172054 A, WO 2019/021975 A, WO 2018/230334 A, WO 2018/194123 A, JP 2018-180525 A, WO 2018/190088 A, JP 2018-070596 A, JP 2018-028090 A, JP 2016-153409 A, JP 2016-130240 A, JP 2016-108325 A, JP 2016-047920 A, JP 2016-035570 A, JP 2016-035567 A, JP 2016-035565 A, JP 2019-101417 A, JP 2019-117373 A, JP 2019-052294 A, JP 2019-008280 A, JP 2019-008279 A, JP 2019-003176 A, JP 2019-003175 A, JP 2018-197853 A, JP 2019-191298 A, JP 2019-061217 A, JP 2018-045152 A, JP 2018-022039 A, JP 2016-090441 A, JP 2015-10878 A, JP 2012-168279 A, JP 2012-022261 A, JP 2012-022258 A, JP 2011-043749 A, JP 2010-181857 A, JP 2010-128369 A, WO 2018/031896 A, JP 2019-113855 A, WO 2017/156388 A, WO 2017/066319 A, JP 2018-41099 A, WO 2016/065120 A, WO 2015/026482 A, JP 2016-29498 A, and JP 2011-253185 A.

Examples of the resist composition include the following compositions.

An active light-sensitive or radiation-sensitive resin composition that contains a resin A including a repeating unit having an acid decomposable group in which a polar group is protected by a protecting group to be removed by the action of an acid, and that contains a compound represented by general formula (21) below.

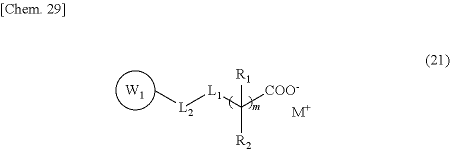

In general formula (21), m represents an integer of 1 to 6.
R₁ and R₂ each independently represent a fluorine atom or a perfluoroalkyl group.
L₁ represents —O—, —S—, —COO—, —SO₂—, or —SO₃—.
L₁ represents an alkylene group which may have a substituent or a single bond.
W₁ represents a cyclic organic group which may have a substituent.
M* represents a cation.

A metal-containing film-forming composition for use in extreme ultraviolet light or electron beam lithography, which contains a compound having a metal-oxygen covalent bond, and a solvent, and in which a metal element constituting the compound belongs to periods 3 to 7 of groups 3 to 15 of the periodic table.

A radiation-sensitive resin composition that contains a polymer having a first structural unit represented by formula (31) below and a second structural unit represented by formula (32) below and containing an acid-dissociable group, and that contains an acid generator.

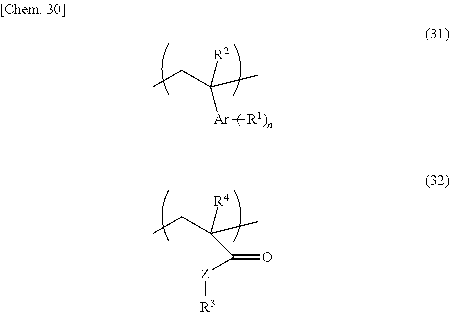

In formula (31), Ar is a group obtained by removing (n+1) hydrogen atoms from an arene having 6 to 20 carbon atoms, R¹ is a hydroxy group, a sulfanyl group, or a monovalent organic group having 1 to 20 carbon atoms, n is an integer of 0 to 11, when n is 2 or more, a plurality of R¹'s are identical or different, and R² is a hydrogen atom, a fluorine atom, a methyl group, or a trifluoromethyl group. In formula (32), R³ is a monovalent group having 1 to 20 carbon atoms and containing the acid-dissociable group, Z is a single bond, an oxygen atom, or a sulfur atom, and R⁴ is a hydrogen atom, a fluorine atom, a methyl group, or a trifluoromethyl group.

A resist composition that contains a resin (A1) including a structural unit having a cyclic carbonate structure, a structural unit represented by a formula below, and a structural unit having an acid-unstable group, and that contains an acid generator.

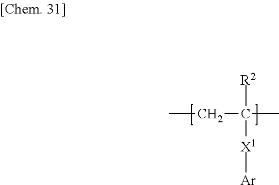

In the formula,
R² represents an alkyl group having 1 to 6 carbon atoms, which may have a halogen atom, a hydrogen atom, or a halogen atom, X¹ represents a single bond, —CO—O—*, or —CO—NR⁴—* where * represents a bond with —Ar, R⁴ represents a hydrogen atom or an alkyl group having 1 to 4 carbon atoms, and Ar represents an aromatic hydrocarbon group having 6 to 20 carbon atoms, which may have one or more groups selected from the group consisting of a hydroxy group and a carboxyl group.

Examples of the resist film include the following.

A resist film containing a base resin including a repeating unit represented by formula (a1) below and/or a repeating unit represented by formula (a2) below, and a repeating unit that generates an acid bonded to a polymer main chain by exposure.

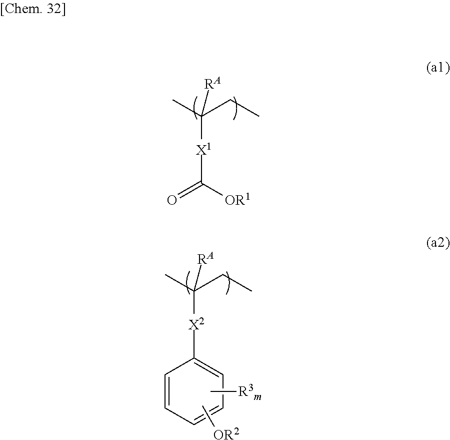

In formula (a1) and formula (a2), R^{A}'s are each independently a hydrogen atom or a methyl group, R¹ and R² are each independently a tertiary alkyl group having 4 to 6 carbon atoms, R³'s are each independently a fluorine atom or a methyl group, m is an integer of 0 to 4, X¹ is a single bond, a phenylene group, or a naphthylene group, or a linking group having 1 to 12 carbon atoms containing at least one selected from an ester bond, a lactone ring, a phenylene group, and a naphthylene group, and X² is a single bond, an ester bond, or an amide bond.

Examples of a resist material include the following.

A resist material containing a polymer having a repeating unit represented by formula (b1) or formula (b2) below.

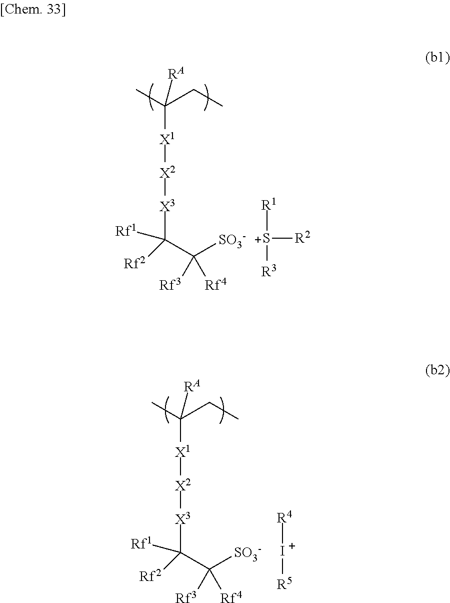

In formula (b1) and formula (b2), R^{A} is a hydrogen atom or a methyl group, X¹ is a single bond or an ester group, X² is a linear, branched, or cyclic alkylene group having 1 to 12 carbon atoms or an arylene group having 6 to 10 carbon atoms, and a methylene group constituting the alkylene group may be partially substituted with an ether group, an ester group, or a lactone ring-containing group, and at least one hydrogen atom contained in X² is substituted with a bromine atom, X³ is a single bond, an ether group, an ester group, or a linear, branched, or cyclic alkylene group having 1 to 12 carbon atoms, and a methylene group constituting the alkylene group may be partially substituted with an ether group or an ester group, Rf¹ to Rf⁴ are each independently a hydrogen atom, a fluorine atom, or a trifluoromethyl group, at least one of Rf¹ to Rf⁴ is a fluorine atom or a trifluoromethyl group, and Rf¹ and Rf² may be combined to form a carbonyl group, R¹ to R⁵ are each independently a linear, branched, or cyclic alkyl group having 1 to 12 carbon atoms, a linear, branched, or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, and some or all of hydrogen atoms of these groups may be substituted with a hydroxy group, a carboxy group, a halogen atom, an oxo group, a cyano group, an amide group, a nitro group, a sultone group, a sulfone group, or a sulfonium salt-containing group, and methylene groups constituting these groups may be partially substituted with an ether group, an ester group, a carbonyl group, a carbonate group, or a sulfonic acid ester group, and R¹ and R² may be bonded to form a ring together with the sulfur atom to which R¹ and R² are bonded.

A resist material containing a base resin containing a polymer including a repeating unit represented by formula (a) below.

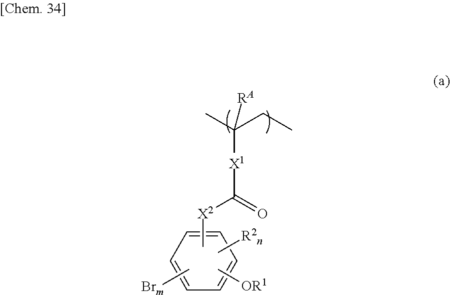

In formula (a), R^{A} is a hydrogen atom or a methyl group, R¹ is a hydrogen atom or an acid-unstable group, R² is a linear, branched, or cyclic alkyl group having 1 to 6 carbon atoms or a halogen atom other than bromine, X¹ is a single bond or a phenylene group, or a linear, branched, or cyclic alkylene group having 1 to 12 carbon atoms which may contain an ester group or a lactone ring, X² is —O—, —O—CH₂—, or —NH—, m is an integer of 1 to 4, and u is an integer of 0 to 3, however, m+u is an integer of 1 to 4.

A resist composition, which generates an acid by exposure and changes its solubility in a developer by the action of an acid, and contains
a base material component (A) that changes its solubility in a developer by the action of an acid, and a fluorine additive component (F) that exhibits decomposability against an alkaline developer, and in which
the fluorine additive component (F) contains a fluororesin component (F1) having a constituent unit (f1) containing a base-dissociable group and a constituent unit (f2) containing a group represented by general formula (f2-r-1) below.

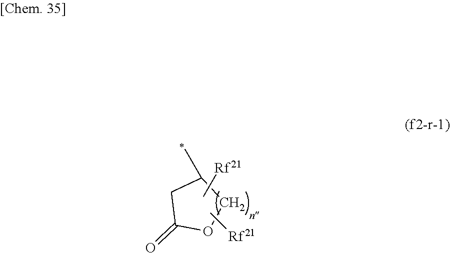

In formula (f2-r-1), Rf²¹'s are each independently a hydrogen atom, an alkyl group, an alkoxy group, a hydroxy group, a hydroxyalkyl group, or a cyano group, n″ is an integer of 0 to 2, and * is a bond.

The constituent unit (f1) includes a constituent unit represented by general formula (f1-1) below or a constituent unit represented by general formula (f1-2) below.

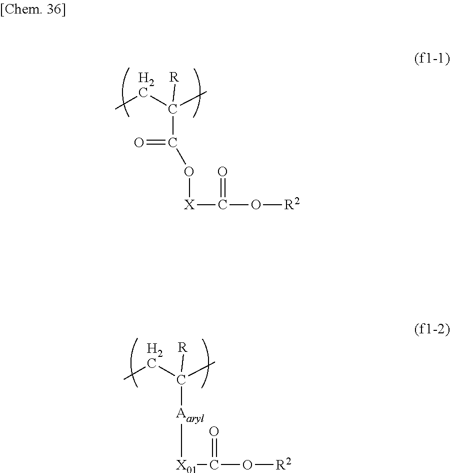

In formulae (f1-1) and (f1-2), R's are each independently a hydrogen atom, an alkyl group having 1 to 5 carbon atoms, or a halogenated alkyl group having 1 to 5 carbon atoms, X is a divalent linking group having no acid-dissociable site, A_{aryl} is a divalent aromatic cyclic group which may have a substituent, X₀₁ is a single bond or a divalent linking group, and R²'s are each independently an organic group having a fluorine atom.

Examples of a coating, a coating solution, and a coating composition include the following.

A coating containing a metal oxo-hydroxo network having an organic ligand through a metal-carbon bond and/or a metal-carboxylate bond.

An inorganic oxo/hydroxo-based composition.

A coating solution containing an organic solvent; a first organometallic composition represented by a formula R₂SnO_{(2-(z/2)-(x/2))} (OH)ₓ (where 0<z≤2 and 0<(z+x)≤4), a formula R′ₙSnX₄₋ₙ (where n=1 or 2), or a mixture thereof, wherein R and R′ are independently a hydrocarbyl group having 1 to 31 carbon atoms, and X is a ligand having a hydrolysable bond to Sn or a combination thereof; and a hydrolysable metal compound represented by a formula MX′ᵥ (where M is a metal selected from groups 2 to 16 of the periodic table of elements, v=a number of 2 to 6, and X′ is a ligand having a hydrolysable M-X bond or a combination thereof).

A coating solution containing an organic solvent and a first organometallic compound represented by a formula RSnO_{(3/2-x/2)} (OH)ₓ (where 0<x<3), wherein the solution contains about 0.0025 M to about 1.5 M of tin and R is an alkyl group or a cycloalkyl group having 3 to 31 carbon atoms and the alkyl group or the cycloalkyl group is bonded to tin at a secondary or tertiary carbon atom.

An inorganic pattern forming precursor aqueous solution containing a mixture of water, a metal suboxide cation, a polyatomic inorganic anion, and a radiation-sensitive ligand containing a peroxide group.

The irradiation with EB or EUV is performed, for example, through a mask (reticle) for forming a predetermined pattern. The composition for forming a resist underlayer film of the present invention is applied for irradiation with an electron beam (EB) or extreme ultraviolet (EUV: 13.5 nm), but is preferably applied for exposure to extreme ultraviolet (EUV).

The irradiation energy of EB and the exposure amount of EUV are not particularly limited.

Bake (post exposure bake: PEB) may be performed after irradiation with EB or EUV and before development.

The baking temperature is not particularly limited, but is preferably 60° C. to 150° C., more preferably 70° C. to 120° C., and particularly preferably 75° C. to 110° C.

The baking time is not particularly limited, but is preferably 1 second to 10 minutes, more preferably 10 seconds to 5 minutes, and particularly preferably 30 seconds to 3 minutes.

In the development, for example, an alkaline developer is used.

Examples of the development temperature include 5° C. to 50° C.

Examples of the developing time include 10 seconds to 300 seconds.

As the alkaline developer, for example, an aqueous solution of an inorganic alkali such as sodium hydroxide, potassium hydroxide, sodium carbonate, sodium silicate, sodium metasilicate, or aqueous ammonia, a primary amine such as ethylamine or n-propylamine, a secondary amine such as diethylamine or di-n-butylamine, a tertiary amine such as triethylamine or methyldiethylamine, an alcohol amine such as dimethylethanolamine or triethanolamine, a quaternary ammonium salt such as tetramethylammonium hydroxide, tetraethylammonium hydroxide, or choline, or a cyclic amine such as pyrrole or piperidine can be used. Further, the aqueous solution of an alkali can also be used by adding an appropriate amount of an alcohol such as isopropyl alcohol or a surfactant such as a nonionic surfactant thereto. Among these, a preferred developer is an aqueous solution of a quaternary ammonium salt, and more preferred developers are an aqueous solution of tetramethylammonium hydroxide and an aqueous solution of choline. Further, a surfactant or the like can also be added to these developers. It is also possible to use a method in which development is performed with an organic solvent such as butyl acetate in place of the alkaline developer and a portion where the alkali dissolution rate of the photoresist is not improved is developed.

Subsequently, the resist underlayer film is etched using the formed resist pattern as a mask. The etching may be dry etching or wet etching, but is preferably dry etching.

When the inorganic film is formed on the surface of a semiconductor substrate used, the surface of the inorganic film is exposed, and when the inorganic film is not formed on the surface of a semiconductor substrate used, the surface of the semiconductor substrate is exposed. Thereafter, the semiconductor substrate is subjected to a step of processing the semiconductor substrate by a known method (a dry etching method or the like), whereby a semiconductor device can be produced.

### EXAMPLES

Next, the contents of the present invention will be specifically described with reference to examples, but the present invention is not limited thereto.

The weight average molecular weight of each of the polymers shown in the following synthesis examples and comparative synthesis examples in the present description is a measurement result by gel permeation chromatography (hereinafter abbreviated as GPC). In the measurement, a GPC apparatus manufactured by Tosoh Corporation was used, and measurement conditions and the like are as follows.
GPC column: TSKgel Super-Multipore HZ—N (two columns)
Column temperature: 40° C.
Solvent: tetrahydrofuran (THF)
Flow rate: 0.35 ml/min
Standard sample: polystyrene (manufactured by Tosoh Corporation)

### Synthesis Example 1

To 29.14 g of propylene glycol monomethyl ether in a reaction vessel, 7.00 g of monoallyl diglycidyl isocyanurate (manufactured by Shikoku Chemicals Corporation), 11.79 g of 3,3′,5,5′-tetrakis(methoxymethyl)-[1,1′-biphenyl]-4,4′-diol (TMOM-BP (trade name), manufactured by Honshu Chemical Industry Co., Ltd.), and 0.64 g of tetrabutylphosphonium bromide (manufactured by Hokko Chemical Industry Co., Ltd.) were added and dissolved therein. The reaction vessel was purged with nitrogen, and then, a reaction was allowed to proceed at 140° C. for 24 hours to obtain a solution containing Polymer 1. As a result of GPC analysis, Polymer 1 obtained had a weight average molecular weight of 8,500 in terms of standard polystyrene and a dispersity of 3.5. The structure present in Polymer 1 is represented by a formula below.

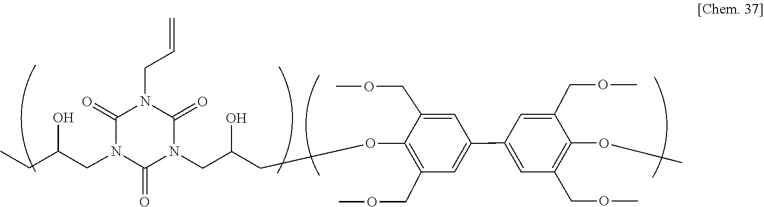

### Synthesis Example 2

To 21.01 g of propylene glycol monomethyl ether in a reaction vessel, 4.49 g of monomethyl diglycidyl isocyanurate (manufactured by Shikoku Chemicals Corporation), 9.06 g of 3,3′,5,5′-tetrakis(methoxymethyl)-[1,1′-biphenyl]-4,4′-diol (TMOM-BP (trade name), manufactured by Honshu Chemical Industry Co., Ltd.), and 0.46 g of tetrabutylphosphonium bromide (manufactured by Hokko Chemical Industry Co., Ltd.) were added and dissolved therein. The reaction vessel was purged with nitrogen, and then, a reaction was allowed to proceed at 140° C. for 24 hours to obtain a solution containing Polymer 2. As a result of GPC analysis, Polymer 2 obtained had a weight average molecular weight of 4,800 in terms of standard polystyrene and a dispersity of 3.1. The structure present in Polymer 2 is represented by a formula below.

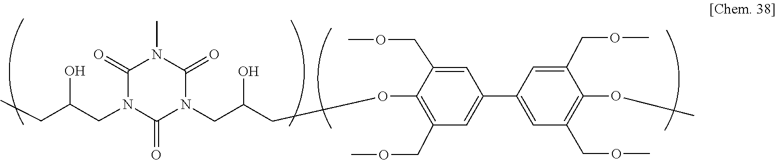

### Synthesis Example 3

To 4.27 g of propylene glycol monomethyl ether in a reaction vessel, 15.00 g of EPICLON WR-400 (trade name) (manufactured by DIC Corporation, a propylene glycol monomethyl ether solution), 2.77 g of 3,3′,5,5′-tetrakis(methoxymethyl)-[1,1′-biphenyl]-4,4′-diol (TMOM-BP (trade name), manufactured by Honshu Chemical Industry Co., Ltd.), and 0.14 g of tetrabutylphosphonium bromide (manufactured by Hokko Chemical Industry Co., Ltd.) were added and dissolved therein. The reaction vessel was purged with nitrogen, and then, a reaction was allowed to proceed at 140° C. for 24 hours to obtain a solution containing Polymer 3. As a result of GPC analysis, Polymer 3 obtained had a weight average molecular weight of 5,300 in terms of standard polystyrene and a dispersity of 3.2. The structure present in Polymer 3 is represented by a formula below.

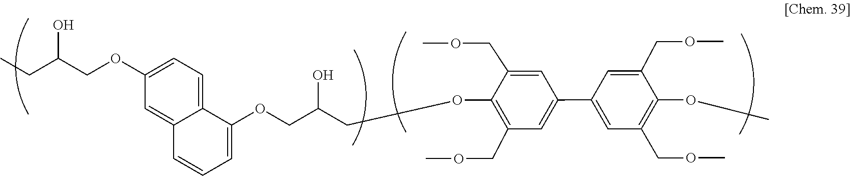

### Synthesis Example 4

To 27.80 g of propylene glycol monomethyl ether in a reaction vessel, 15.00 g of EPICLON WR-600 (trade name) (manufactured by DIC Corporation, a propylene glycol monomethyl ether solution), 4.78 g of 3,3′,5,5′-tetrakis(methoxymethyl)-[1,1′-biphenyl]-4,4′-diol (TMOM-BP (trade name), manufactured by Honshu Chemical Industry Co., Ltd.), and 0.24 g of tetrabutylphosphonium bromide (manufactured by Hokko Chemical Industry Co., Ltd.) were added and dissolved therein. The reaction vessel was purged with nitrogen, and then, a reaction was allowed to proceed at 140° C. for 24 hours to obtain a solution containing Polymer 4. As a result of GPC analysis, Polymer 4 obtained had a weight average molecular weight of 8,000 in terms of standard polystyrene and a dispersity of 4.7.

### Synthesis Example 5

To 39.74 g of propylene glycol monomethyl ether in a reaction vessel, 4.00 g of EPICLON HP-4770 (trade name) (manufactured by DIC Corporation), 5.69 g of 3,3′,5,5′-tetrakis(methoxymethyl)-[1,1′-biphenyl]-4,4′-diol (TMOM-BP (trade name), manufactured by Honshu Chemical Industry Co., Ltd.), and 0.25 g of tetrabutylphosphonium bromide (manufactured by Hokko Chemical Industry Co., Ltd.) were added and dissolved therein. The reaction vessel was purged with nitrogen, and then, a reaction was allowed to proceed at 140° C. for 24 hours to obtain a solution containing Polymer 5. As a result of GPC analysis, Polymer 5 obtained had a weight average molecular weight of 13,200 in terms of standard polystyrene and a dispersity of 9.6.

### Synthesis Example 6

To 20.56 g of propylene glycol monomethyl ether in a reaction vessel, 5.00 g of monoallyl diglycidyl isocyanurate (manufactured by Shikoku Chemicals Corporation), 6.48 g of 3,3′,5,5′-tetrakis(methoxymethyl)-[1,1′-biphenyl]-4,4′-diol (TMOM-BP (trade name), manufactured by Honshu Chemical Industry Co., Ltd.), 1.77 g of 4-iodobenzoic acid (manufactured by Tokyo Chemical Industry Co., Ltd.), and 0.46 g of tetrabutylphosphonium bromide (manufactured by Hokko Chemical Industry Co., Ltd.) were added and dissolved therein The reaction vessel was purged with nitrogen, and then, a reaction was allowed to proceed at 140° C. for 24 hours to obtain a solution containing Polymer 6. As a result of GPC analysis, Polymer 6 obtained had a weight average molecular weight of 4,000 in terms of standard polystyrene and a dispersity of 3.9. The structure present in Polymer 6 is represented by a formula below.

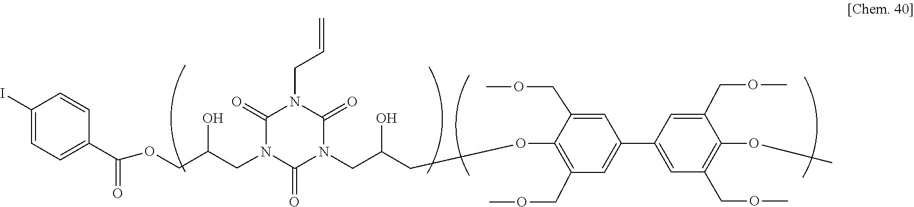

### Synthesis Example 7

To 49.10 g of propylene glycol monomethyl ether in a reaction vessel, 7.00 g of EPICLON HP-4770 (trade name) (manufactured by DIC Corporation), 1.92 g of 5,5-diethylbarbituric acid (manufactured by Tateyama Kasei Co., Ltd.), 1.43 g of 3,5-diiodosalicylic acid (manufactured by Tokyo Chemical Industry Co., Ltd.), and 0.31 g of tetrabutylphosphonium bromide (manufactured by Hokko Chemical Industry Co., Ltd.) were added and dissolved therein. The reaction vessel was purged with nitrogen, and then, a reaction was allowed to proceed at 140° C. for 24 hours to obtain a solution containing Polymer 7. As a result of GPC analysis, Polymer 7 obtained had a weight average molecular weight of 3,200 in terms of standard polystyrene and a dispersity of 3.7.

### Synthesis Example 8

In a reaction vessel, 260.00 g of TMOM-BP (manufactured by Honshu Chemical Industry Co., Ltd.) and 1,430 g of propylene glycol monomethyl ether acetate (PGME) were placed. Thereafter, the mixture was heated to about 90° C. under nitrogen, 17.26 g of methanesulfonic acid (manufactured by Tokyo Chemical Industry Co., Ltd.) dissolved in 130.00 g of PGME was added dropwise thereto, and after about 45 hours, a reaction product was precipitated with methanol and water and dried to obtain Polymer 8. In the actual structural unit, an arbitrary ROCH₂— group containing a methoxymethyl group and a hydroxy group or ROCH₂— groups are bonded and crosslinked, but when the state is shown in a chemical formula, it becomes extremely complicated, and thus only the structural unit is shown. As a result of GPC analysis, Polymer 8 obtained had a weight average molecular weight of 4,500 in terms of standard polystyrene. The structure present in Polymer 8 is represented by a formula below.

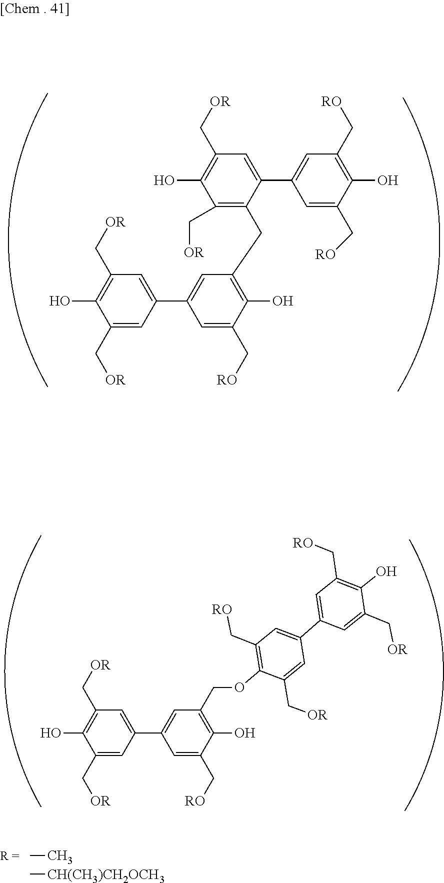

### Comparative Synthesis Example 1

To 682.00 g of propylene glycol monomethyl ether in a reaction vessel, 100.00 g of monoallyl diglycidyl isocyanurate (manufactured by Shikoku Chemicals Corporation), 66.4 g of 5,5-diethylbarbituric acid (manufactured by Tateyama Kasei Co., Ltd.), and 4.1 g of benzyltriethylammonium chloride were added and dissolved therein. The reaction vessel was purged with nitrogen, and then, a reaction was allowed to proceed at 130° C. for 24 hours to obtain a solution containing Comparative Polymer 1. As a result of GPC analysis, Comparative Polymer 1 obtained had a weight average molecular weight of 6,800 in terms of standard polystyrene and a dispersity of 4.8. The structure present in Comparative Polymer 1 is represented by a formula below.

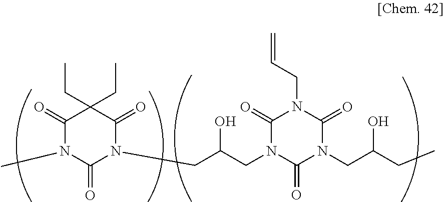

### (Preparation of Resist Underlayer Film)

### Examples and Comparative Example

The respective components were mixed at the proportions shown in Table 1, and the mixture was filtered through a fluororesin filter having a pore size of 0.1 μm to prepare each of compositions for forming a resist underlayer film for use in EB or EUV lithography of Examples 1 to 24 and a composition for forming a resist underlayer film of Comparative Example 1.

Abbreviations in Table 1 are as follows.
PL-LI: tetramethoxymethyl glycoluril
PyPSA: pyridinium p-hydroxybenzenesulfonate
R-30N: surfactant (trade name: R-40, manufactured by DIC Corporation)
PGMEA: propylene glycol monomethyl ether acetate
PGME: propylene glycol monomethyl ether
GPCL-11: a polymer having the following repeating unit (trade name: GPCL-11, manufactured by Gun Ei Chemical Industry Co., Ltd.)

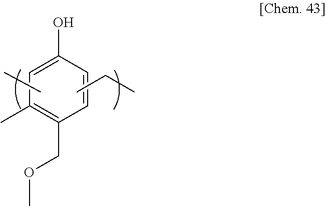

GPCL-20: a polymer having the following repeating unit (trade name: GPCL-20, manufactured by Gun Ei Chemical Industry Co., Ltd.)

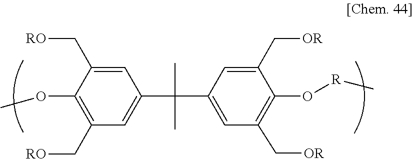

NIKALAC Mw-390: 2,4,6-Tris[bis(methoxymethyl)amino]-1,3,5-triazine (trade name: NIKALAC Mw-390, manufactured by Sanwa Chemical Co., Ltd., structural formula below)

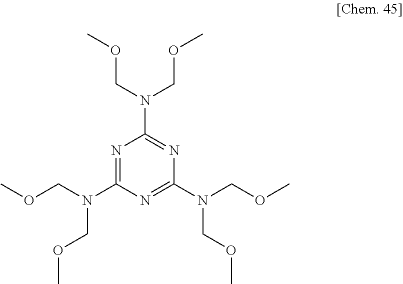

TMOM-BP: 3,3′,5,5′-tetrakis(methoxymethyl)-[1,1′-biphenyl]-4,4′-diol (trade name: TMOM-BP, manufactured by Honshu Chemical Industry Co., Ltd., substructural formula)

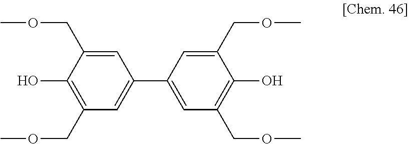

PGME-BIP-A: Phenol, 4,4′-(1-methylethylidene)bis(2,6-bis[(2-methoxy-1-methylethoxy)methyl]-(substructural formula)

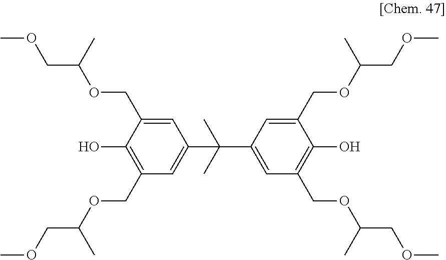

TM-BIP-ANT: 1,3-Benzenedimethanol, 2-hydroxy-5-[[10-[4-hydroxy-3,5-bis(hydroxymethyl) phenol]-9-anthracenyl]methyl]-(substructural formula)

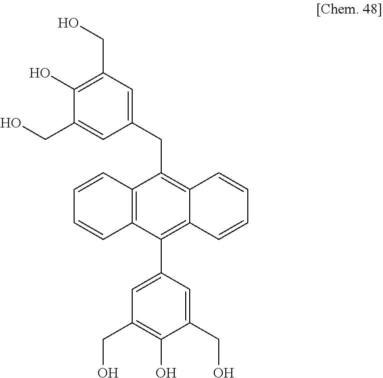 [SMILES: OCc1cc(Cc2c3ccccc3c(-c3cc(CO)c(O)c(CO)c3)c3ccccc23)cc(CO)c1O]

BIP-PHBZ-6MX: 1,1,1-Tris(3,5-dimethoxymethyl-4-hydroxyphenyl)methane (substructural formula)

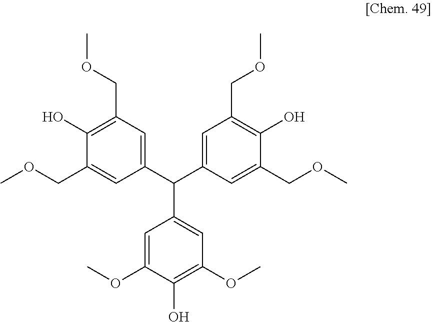

HMOM-TPPA: Phenol, 4,4′-[1-[4-[1-[4-hydroxy-3,5-bis(methoxymethyl)phenyl]-1-methylethyl]phenyl]ethylidene]bis[2,6-bis(methoxymethyl)-(substructural formula)

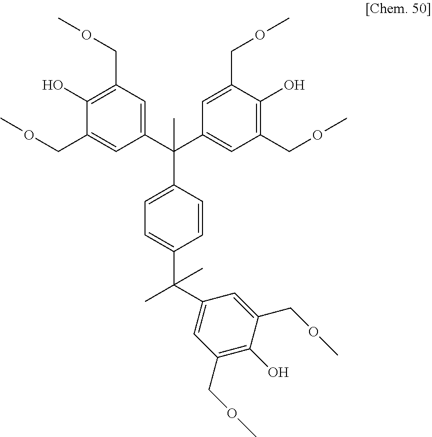

TPA-8 MX: α,α,α′,α′-Tetrakis(3,5-dimethoxymethyl-4-hydroxyphenyl)-p-xylene (substructural formula)

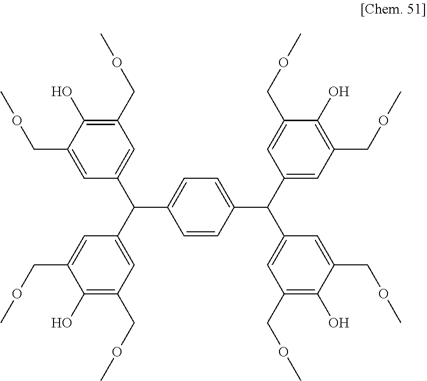

GPCL-05: a polymer having the following repeating unit (trade name: GPCL-05, manufactured by Gun Ei Chemical Industry Co., Ltd.)

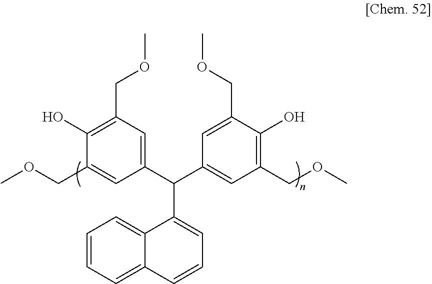

GPCL-25: a compound having the following repeating unit (trade name: GPCL-25, manufactured by Gun Ei Chemical Industry Co., Ltd.)

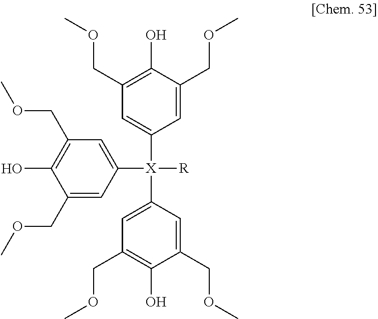

TABLE 1

| | | | Curing | | | |
|---|---|---|---|---|---|---|
| | Component 1 | Component 2 | catalyst | Surfactant | Solvent | |
| Example 1 | Polymer 1 | — | PyPSA | — | PGME | PGMEA |
| (parts by | 0.151 | — | 0.004 | — | 90 | 10 |
| mass) | | | | | | |
| Example 2 | Polymer 2 | — | PyPSA | — | PGME | PGMEA |
| (parts by | 0.155 | — | 0.002 | — | 70 | 30 |
| mass) | | | | | | |
| Example 3 | Polymer 3 | — | PyPSA | — | PGME | PGMEA |
| (parts by | 0.158 | — | 0.002 | — | 70 | 30 |
| mass) | | | | | | |
| Example 4 | Polymer 4 | — | PyPSA | — | PGME | PGMEA |
| (parts by | 0.156 | — | 0.004 | — | 70 | 30 |
| mass) | | | | | | |
| Example 5 | GPCL-11 | — | — | — | PGME | PGMEA |
| (parts by | 0.180 | — | — | — | 30 | 70 |
| mass) | | | | | | |
| Example 6 | Polymer 6 | — | PyPSA | — | PGME | PGMEA |
| (parts by | 0.180 | — | 0.005 | — | 70 | 30 |
| mass) | | | | | | |
| Example 7 | GPCL-20 | — | PyPSA | — | PGME | PGMEA |
| (parts by | 0.180 | — | 0.005 | — | 70 | 30 |
| mass) | | | | | | |
| Example 8 | Polymer 7 | Polymer 8 | PyPSA | — | PGME | PGMEA |
| (parts by | 0.127 | 0.045 | 0.003 | — | 70 | 30 |
| mass) | | | | | | |
| Example 9 | Polymer 7 | GPCL-11 | PyPSA | — | PGME | PGMEA |
| (parts by | 0.124 | 0.043 | 0.003 | — | 70 | 30 |
| mass) | | | | | | |
| Example 10 | NIKALAC | — | PyPSA | — | PGME | PGMEA |
| | MW-390 | | | | | |
| (parts by | 0.390 | — | 0.010 | — | 90 | 10 |
| mass) | | | | | | |
| Example 11 | TMOM-BP | — | PyPSA | — | PGME | PGMEA |
| (parts by | 0.390 | | 0.010 | — | 90 | 10 |
| mass) | | | | | | |
| Example 12 | PGME-BIP-A | — | PyPSA | — | PGME | PGHEA |
| (parts by | 0.390 | — | 0.010 | — | 90 | 10 |
| mass) | | | | | | |
| Example 13 | GPCL-05 | — | PyPSA | — | PGME | PGMEA |
| (parts by | 0.187 | — | 0.003 | — | 30 | 70 |
| mass) | | | | | | |
| Example 14 | TM-BIP-ANT | — | — | — | PGME | PGMEA |
| (parts by | 0.190 | — | — | — | 70 | 30 |
| mass) | | | | | | |
| Example 15 | GPCL-25 | — | PyPSA | — | PGME | PGMEA |
| (parts by | 0.179 | — | 0.001 | — | 30 | 70 |
| mass) | | | | | | |
| Example 16 | BIP-PHBZ-6MX | — | PyPSA | — | PGME | PGMEA |
| (parts by | 0.189 | — | 0.001 | — | 70 | 30 |
| mass) | | | | | | |
| Example 17 | HMOM-TPPA | — | PyPSA | — | PGME | PGMEA |
| (parts by | 0.169 | — | 0.001 | — | 90 | 10 |
| mass) | | | | | | |
| Example 18 | TPA-8MX | — | PyPSA | — | PGME | PGMEA |
| (parts by | 0.224 | — | 0.006 | — | 90 | 10 |
| mass) | | | | | | |
| Example 19 | Polymer 7 | GPCL-05 | PyPSA | — | PGME | PGMEA |
| (parts by | 0.127 | 0.045 | 0.003 | — | 70 | 30 |
| mass) | | | | | | |
| Example 20 | Polymer 7 | TM-BIP-ANT | PyPSA | — | PGME | PGMEA |
| (parts by | 0.127 | 0.045 | 0.003 | — | 70 | 30 |
| mass) | | | | | | |
| Example 21 | Polymer 7 | GPCL-25 | PyPSA | — | PGME | PGMEA |
| (parts by | 0.127 | 0.045 | 0.003 | — | 70 | 30 |
| mass) | | | | | | |
| Example 22 | Polymer 7 | BIP-PHBZ-6MX | PyPSA | — | PGME | PGMEA |
| (parts by | 0.127 | 0.045 | 0.003 | — | 70 | 30 |
| mass) | | | | | | |
| Example 23 | Polymer 7 | HMOM-TPPA | PyPSA | — | PGME | PGMEA |
| (parts by | 0.127 | 0.045 | 0.003 | — | 70 | 30 |
| mass) | | | | | | |
| Example 24 | Polymer 7 | TPA-8MX | PyPSA | — | PGHE | PGMEA |
| (parts by | 0.127 | 0.045 | 0.003 | — | 70 | 30 |
| mass) | | | | | | |
| Comparative | Comparative | PL-LI | PyPSA | R-30N | PGME | PGMEA |
| Example 1 | Polymer 1 | | | | | |
| (parts by | 0.149 | 0.037 | 0.003 | 0.001 | 70 | 30 |
| mass) | | | | | | |

### (Elution Test in Photoresist Solvent)

Each of the compositions for forming a resist underlayer film for use in EB or EUV lithography of Examples 1 to 24 and the composition for forming a resist underlayer film of Comparative Example 1 was applied onto a silicon wafer using a spinner. The silicon wafer was baked at 205° C. for 60 seconds on a hot plate to obtain a film having a film thickness of 5 nm. These resist underlayer films were immersed in a mixed solution of propylene glycol monomethyl ether/propylene glycol monomethyl ether acetate=70/30 (volume ratio), which is a solvent used for the photoresist, and a case where the film thickness change was less than 5 Å was evaluated as good, and a case where the film thickness change was 5 Å or more was evaluated as poor, and the results are shown in Table 2.

TABLE 2

| | Elution test |
|---|---|
| Example 1 | good |
| Example 2 | good |
| Example 3 | good |
| Example 4 | good |
| Example 5 | good |
| Example 6 | good |
| Example 7 | good |
| Example 8 | good |
| Example 9 | good |
| Example 10 | good |
| Example 11 | good |
| Example 12 | good |
| Example 13 | good |
| Example 14 | good |
| Example 15 | good |
| Example 16 | good |
| Example 17 | good |
| Example 18 | good |
| Example 19 | good |
| Example 20 | good |
| Example 21 | good |
| Example 22 | good |
| Example 23 | good |
| Example 24 | good |
| Comparative Example 1 | good |

### (Evaluation of Resist Patterning)

### [Test of Resist Pattern Formation by Electron Beam Lithography System]

Each of the compositions for forming a resist underlayer film of Examples 1 to 5, 8 to 17, and 19 to 24 and Comparative Example 1 was applied onto a silicon wafer using a spinner. The silicon wafer was baked at 205° C. for 60 seconds on a hot plate to obtain a resist underlayer film having a film thickness of 5 nm. A positive resist solution for EUV was spin-coated on the resist underlayer film, followed by heating to 130° C. for 60 seconds to form an EUV resist film. The resist film was irradiated with EB under predetermined conditions using an electron beam lithography system (ELS-G130). After irradiation, bake (PEB) was performed at 90° C. for 60 seconds and cooled to room temperature on a cooling plate, and paddle development was performed for 30 seconds using a 2.38% aqueous tetramethylammonium hydroxide solution (trade name NMD-3 manufactured by TOKYO OHKA KOGYO CO., LTD.) as a photoresist developer. A resist pattern having a line size of 16 nm to 28 nm was formed. A scanning electron microscope (CG4100 manufactured by Hitachi High-Technologies Corporation) was used for measuring the length of the resist pattern.

With respect to the photoresist pattern thus obtained, whether or not a 22 nm line-and-space (L/S) could be formed was evaluated. In Examples 1 to 5, 8 to 17, and 19 to 24, 22 nm L/S pattern formation was observed. In addition, the amount of charge with which the 22 nm line/44 nm pitch (line-and-space (L/S=1/1) was formed is defined as the optimal irradiation energy, and the irradiation energy (μC/cm²) and the LWR at that time are shown in Table 3. In Examples 1 to 5, 8 to 17, and 19 to 24, improvement in LWR and improvement in minimum CD size as compared with Comparative Example 1 were observed.

As the minimum CD size, a limit CD size at which no pattern collapse occurs is indicated, and as the LWR, a value in the 22 nmL/S pattern is indicated.

TABLE 3

| | Irradiation energy | Minimum CD size | LWR |
|---|---|---|---|
| | (μC/cm²) | (nm) | (nm) |
| Example 1 | 458 | 18.6 | 3.19 |
| Example 2 | 493 | 18.9 | 3.17 |
| Example 3 | 484 | 18.6 | 3.15 |
| Example 4 | 491 | 18.8 | 3.23 |
| Example 5 | 496 | <17.4 | 3.05 |
| Example 8 | 475 | 18.6 | 3.27 |
| Example 9 | 463 | 18.2 | 3.38 |
| Example 10 | 501 | 17.6 | 3.11 |
| Example 11 | 492 | 17.1 | 3.11 |
| Example 12 | 467 | 16.8 | 3.11 |
| Example 13 | 498 | 17.6 | 2.96 |
| Example 14 | 473 | 18.4 | 3.30 |
| Example 15 | 494 | <17.4 | 3.08 |
| Example 16 | 490 | 17.2 | 3.05 |
| Example 17 | 471 | 17.4 | 3.03 |
| Example 19 | 465 | 18.6 | 3.36 |
| Example 20 | 472 | 18.7 | 3.28 |
| Example 21 | 481 | 19.0 | 3.47 |
| Example 22 | 469 | 19.0 | 3.36 |
| Example 23 | 449 | 18.8 | 3.40 |
| Example 24 | 454 | 19.8 | 3.47 |
| Comparative Example 1 | 496 | 20.4 | 3.51 |

In Examples 1 to 24 in which the content of the specific structure-containing component in the film-forming component is 20 mass % or more, the LWR of the resist pattern could be reduced as compared with Comparative Example 1 in which the content of the specific structure-containing component in the film-forming component is less than 20 masse.

1. A composition for forming a resist underlayer film for use in EB or EUV lithography, the composition comprising a film-forming component and a solvent, wherein
the film-forming component contains 20 mass % or more of a specific structure-containing component containing at least either of a first structure containing an aromatic ring and a second structure containing a nitrogen atom,
the first structure contains a group represented by formula (1) below directly bonded to the aromatic ring, and
the second structure contains a group represented by formula (1) below directly bonded to the nitrogen atom: 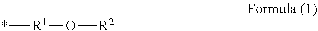
in formula (1), R¹ represents an alkylene group having 1 to 6 carbon atoms, R² represents a hydrogen atom, an alkyl group having 1 to 6 carbon atoms, or an alkoxyalkyl group having 2 to 10 carbon atoms in total, and * represents a bond.

2. The composition for forming a resist underlayer film for use in EB or EUV lithography according to claim 1, wherein
the specific structure-containing component contains a polymer, and
the polymer contains at least either of the first structure and the second structure.

3. The composition for forming a resist underlayer film for use in EB or EUV lithography according to claim 2, wherein the polymer contains, as the first structure, at least any of a structure represented by formula (11) below, a structure represented by formula (12) below, and a structure represented by formula (13) below: 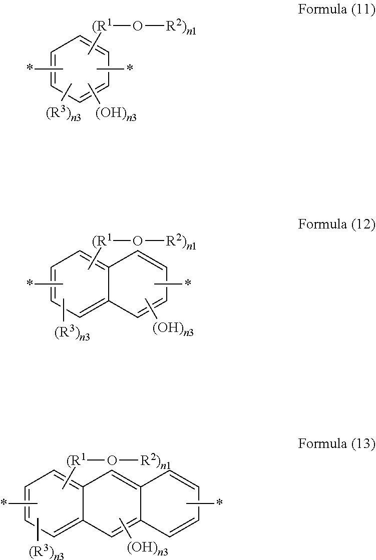
in formula (11) to formula (13), R¹'s each independently represent an alkylene group having 1 to 6 carbon atoms, R²'s each independently represent a hydrogen atom, an alkyl group having 1 to 6 carbon atoms, or an alkoxyalkyl group having 2 to 10 carbon atoms in total, R³'s each independently represent an alkyl group having 1 to 6 carbon atoms, and * represents a bond;
in formula (11), n1 represents an integer of 1 to 4, n2 represents an integer of 0 to 3, n3 represents an integer of 0 to 3, and n1, n2, and n3 satisfy 1≤(n1+n2+n3)≤4;
in formula (12), n1 represents an integer of 1 to 6, n2 represents an integer of 0 to 5, n3 represents an integer of 0 to 5, and n1, n2, and n3 satisfy 1≤(n1+n2+n3)≤6;
in formula (13), n1 represents an integer of 1 to 8, n2 represents an integer of 0 to 7, n3 represents an integer of 0 to 7, and n1, n2, and n3 satisfy 1≤(n1+n2+n3)≤8;
in formula (11) to formula (13), when there are two or more R¹'s, the two or more R¹'s may be identical or different, when there are two or more R²'s, the two or more R²'s may be identical or different, and when there are two or more R³'s, the two or more R³'s may be identical or different.

4. The composition for forming a resist underlayer film for use in EB or EUV lithography according to claim 3, wherein the polymer includes, as a repeating unit containing the structure represented by formula (11), at least either of a repeating unit represented by formula (11-1) below and a repeating unit represented by formula (11-2) below: 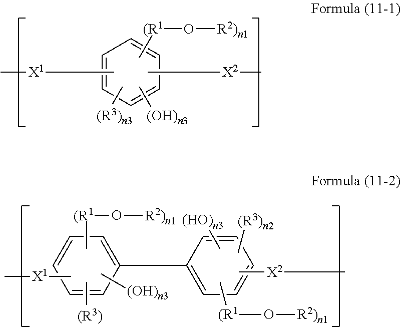
in formula (11-1) and formula (11-2), R¹'s each independently represent an alkylene group having 1 to 6 carbon atoms, R²'s each independently represent a hydrogen atom, an alkyl group having 1 to 6 carbon atoms, or an alkoxyalkyl group having 2 to 10 carbon atoms in total, R³'s each independently represent an alkyl group having 1 to 6 carbon atoms, n1's each independently represent an integer of 1 to 4, n2's each independently represent an integer of 0 to 3, and n3's each independently represent an integer of 0 to 3;
in formula (11-1), X¹ and X² each independently represent a single bond, an oxygen atom, or a methylene group;
in formula (11-2), X¹ and X² each independently represent a single bond, an oxygen atom, or a methylene group, and X³ represents a single bond or a divalent organic group having 1 to 15 carbon atoms;
in formula (11-1), n1, n2, and n3 satisfy 1≤(n1+n2+n3)≤4;
in formula (11-2), n1, n2, and n3 in a benzene ring on a left side satisfy 1≤(n1+n2+n3)≤4, and n1, n2, and n3 in a benzene ring on a right side satisfy 1≤(n1+n2+n3)≤4; and
in formula (11-1) and formula (11-2), when there are two or more R¹'s, the two or more R¹'s may be identical or different, when there are two or more R²'s, the two or more R²'s may be identical or different, and when there are two or more R³'s, the two or more R³'s may be identical or different.

5. The composition for forming a resist underlayer film for use in EB or EUV lithography according to claim 2, wherein the polymer includes a repeating unit represented by formula (14) below: 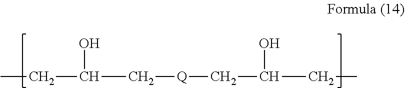
in formula (14), Q represents a divalent group.

6. The composition for forming a resist underlayer film for use in EB or EUV lithography according to claim 5, wherein in formula (14), Q represents a divalent group represented by formula (14-1) below or an arylene group having 6 to 40 carbon atoms: 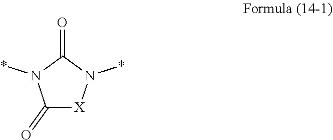
in formula (14-1), X represents a group represented by any of formulae (14-1a) to (14-1c) below: 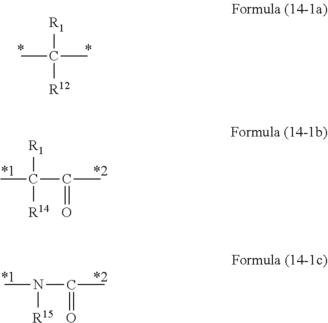
in formulae (14-1a) to (14-1c), R¹¹, R¹², R¹³, R¹⁴, and R¹⁵ each independently represent a hydrogen atom, an alkyl group having 1 to 6 carbon atoms, an alkenyl group having 3 to 6 carbon atoms, a benzyl group, or a phenyl group, and the benzyl group and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms, R¹¹ and R¹² may be bonded to each other to form a ring having 3 to 6 carbon atoms, R¹³ and R¹⁴ may be bonded to each other to form a ring having 3 to 6 carbon atoms, represents a bond, *1 represents a bond bonded to a carbon atom, and *2 represents a bond bonded to a nitrogen atom.

7. The composition for forming a resist underlayer film for use in EB or EUV lithography according to claim 1, wherein the specific structure-containing component contains a crosslinking agent, and
the crosslinking agent contains at least any of a compound represented by formula (21) below, a compound represented by formula (22) below, and a compound represented by formula (23) below: 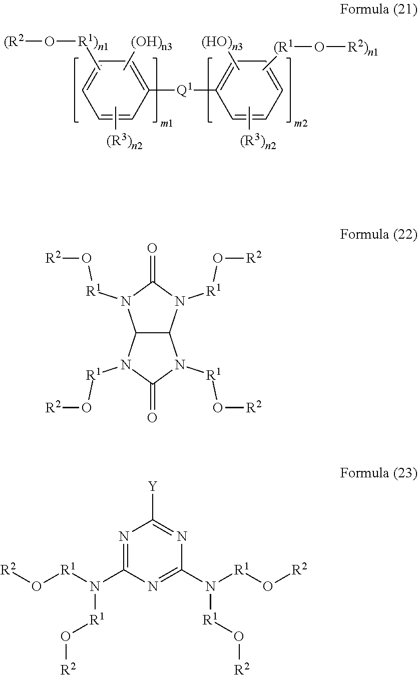
in formula (21) to formula (23), R¹'s each independently represent an alkylene group having 1 to 6 carbon atoms, R²'s each independently represent a hydrogen atom, an alkyl group having 1 to 6 carbon atoms, or an alkoxyalkyl group having 2 to 10 carbon atoms in total, and R³'s each independently represent an alkyl group having 1 to 6 carbon atoms;
in formula (21), m1 and m2 each independently represent an integer of 1 to 2, when m1 and m2 are each 1, Q¹ represents a single bond, an oxygen atom, or a divalent organic group having 1 to 20 carbon atoms, and when a sum of m1 and m2 is 3 or 4, Q¹ represents a (m1+m2)-valent organic group having 1 to 20 carbon atoms;
in formula (21), n1's each independently represent an integer of 1 to 5, n2's each independently represent an integer of 0 to 4, and n3's each independently represent an integer of 0 to 4, in each benzene ring, n1, n2, and n3 satisfy 1≤(n1+n2+n3)≤5; and
in formula (23), Y represents a monovalent organic group having 1 to 20 carbon atoms.

8. The composition for forming a resist underlayer film for use in EB or EUV lithography according to claim 7, wherein the film-forming component contains a polymer that is not the specific structure-containing component.

9. The composition for forming a resist underlayer film for use in EB or EUV lithography according to claim 1, wherein the film-forming component further contains a curing catalyst.

10. The composition for forming a resist underlayer film for use in EB or EUV lithography according to claim 1, wherein the composition is used for forming a resist underlayer film for use in EB or EUV lithography having a film thickness of 10 nm or less.

11. A resist underlayer film for use in EB or EUV lithography, which is a cured product of the composition for forming a resist underlayer film for use in EB or EUV lithography according to claim 1.

12. A substrate for semiconductor processing comprising:
a semiconductor substrate; and
the resist underlayer film for use in EB or EUV lithography according to claim 11.

13. A method for producing a semiconductor element, the method comprising the steps of:
forming a resist underlayer film on a semiconductor substrate using the composition for forming a resist underlayer film for use in EB or EUV lithography according to any-ene claim 1; and
forming a resist film on the resist underlayer film using a resist for use in EB or EUV lithography.

14. A method for forming a pattern, the method comprising the steps of:
forming a resist underlayer film on a semiconductor substrate using the composition for forming a resist underlayer film for use in EB or EUV lithography according to any-ene claim 1;
forming a resist film on the resist underlayer film using a resist for use in EB or EUV lithography;
irradiating the resist film with EB or EUV, and then developing the resist film to obtain a resist pattern; and
etching the resist underlayer film using the resist pattern as a mask.

15. A method for improving LWR of a resist pattern, the method comprising the steps of:
forming a resist underlayer film on a semiconductor substrate using the composition for forming a resist underlayer film for use in EB or EUV lithography according to claim 1;
forming a resist film on the resist underlayer film using a resist for use in EB or EUV lithography; and
irradiating the resist film with EB or EUV, and then developing the resist film to obtain a resist pattern.
